(19) United States
(12) Patent Application Publication
(10) Pub. No.: US 2026/0135346 A1
(43) Pub. Date: May 14, 2026

(54) LASER CHIP, SELECTOR OF AN OPTICAL TRANSCEIVER, AND METHOD FOR MANAGING MULTIPLE LASER CHANNELS

(71) Applicant: PhotonIX Labs, LLC, Foster City (CA)

(72) Inventor: Patrick Chiang, Foster City, CA (US)

(21) Appl. No.: 19/385,368

(22) Filed: Nov. 11, 2025

Related U.S. Application Data
(60) Provisional application No. 63/720,298, filed on Nov. 14, 2024.
(60) Provisional application No. 63/720,287, filed on Nov. 14, 2024.

(51) Int. Cl. H01S 5/042

(52) U.S. Cl. CPC H01S 5/0428

(57) ABSTRACT

A laser chip includes: a plurality of main laser drivers, configured for providing a plurality of pulsed currents; a plurality of main semiconductor lasers, configured for providing a plurality of main optical signals in response to the plurality of pulsed currents respectively; at least one backup semiconductor lasers; and at least one selector, configured for selecting one or more of the plurality of main semiconductor lasers, and, selecting one or more of the at least one backup semiconductor lasers to replace the selected one or more of the plurality of main semiconductor lasers, such that the selected one or more of the at least one backup semiconductor lasers provides one or more backup optical signals that serves to replace one or more of the plurality of main optical signals associated with the selected one or more of the plurality of main semiconductor lasers.

### CROSS-REFERENCE TO RELATED APPLICATIONS

The present application claims priority to U.S. provisional application No. 63/720287, filed on November 14, 2024, and U.S. provisional application No. 63/720298, filed on November 14, 2024, the contents of which are incorporated by reference in their entirety.

### FIELD OF THE INVENTION

The present disclosure relates to the field of optoelectronic technologies. More specifically, the present disclosure relates to techniques for a laser chip, a selector of an optical transceiver, and a method for managing multiple laser channels.

### BACKGROUND OF THE INVENTION

Artificial intelligence (AI) technologies produce enormous amounts of data to be efficiently processed, routed, and stored. AI-driven data centers, or in a more general concept, AI infrastructures, play a critical role in the development and implementation of AI-related technologies, covering a broad spectrum of industries such as manufacturing, transportation, retail, robots, computers, and communications. AI-driven data centers have demands for higher bandwidth, faster speeds, lower latency, scalability for handling increased data volumes, energy efficiency and cost efficiency. Devices and components based on optoelectronic technologies are introduced to AI-driven data centers for handling the extreme AI workloads with respect to processing and routing. Within a data center, with the development of AI models such as large-language-model (LLM), AI applications require higher data rate like 400 gigabytes (GB), 800 GB, and even 1.6 terabytes (TB). Optical interconnects are introduced to help increase data throughput and reduce latency, so as to meet the demands of intra-data center networks of AI-driven data centers. An optical transceiver allows the interconversion of optical and electrical signals during the data transmission, and may be deployed as components for transmission, reception, laser chips, photodetector chips, and other internal components for optical interconnects in an AI-driven data center. At the transmitting end (TX), the optical transceiver converts electrical signals into optical signals that are sent via fiber optic medium, and then optical signals are transformed back into electrical signals at the receiving end (RX). Optical transceivers are widely adopted to create high-speed optical connectors, for connecting graphics processing units (GPUs), central processing units (CPUs), and storage networks. Typically, an optical transceiver has a number of semiconductor lasers, such as Vertical-Cavity Surface-Emitting Lasers (VCSELs). A number of VCSELs may form VCSEL arrays that surround a GPU from different directions with bundles of fibers routed from TX to RX, and this provides an optical solution with cost efficiency. VCSEL reliability becomes a serious concern that may affect system performance because a VCSEL may have its performance deteriorating due to high temperature caused by transceiver heat and other reasons like moisture corrosion. However, since the VCSEL array or a whole VCSEL chip is usually placed next to GPUs to be integrated, it is not possible to detach a VCSEL chip from a GPU to which the VCSEL chip is connected, and therefore, there is no way to replace a malfunctioning VCSEL of a VCSEL chip.

In light of the above, the present disclosure provides a laser chip, a selector of an optical transceiver, and a method for managing multiple laser channels, which provide an optoelectronic solution for optical connectors used in AI-driven data centers, with good reliability and cost efficiency.

### SUMMARY OF THE INVENTION

In accordance with a first aspect, the present disclosure provides a laser chip. The laser chip includes: a plurality of main laser drivers, configured for providing a plurality of pulsed currents; a plurality of main semiconductor lasers, configured for providing a plurality of main optical signals in response to the plurality of pulsed currents respectively; at least one backup semiconductor lasers; and at least one selector, configured for selecting one or more of the plurality of main semiconductor lasers, and, selecting one or more of the at least one backup semiconductor lasers to replace the selected one or more of the plurality of main semiconductor lasers, such that the selected one or more of the at least one backup semiconductor lasers provides one or more backup optical signals that serves to replace one or more of the plurality of main optical signals associated with the selected one or more of the plurality of main semiconductor lasers.

With reference to the first aspect, the architecture and selection mechanism of the laser chip provides an optoelectronic solution for optical connectors used in AI-driven data centers, with good reliability and cost efficiency. The architecture of the laser chip provides several aspects for parametrization of the laser chip for optimization, including the level of redundancy, i.e., the number of the backup semiconductor lasers relative to the number of main semiconductor lasers, the implementation details of the at least one selector, the placement of the selectors before or after the laser drivers, the installment of additional optic fiber cables. As such, the architecture of the laser chip provides several aspects for parametrization, for configuring the laser chip to reach a well balance among different factors like system stability, cost efficiency, system bandwidth, cost sensitiveness, and circuit area. Therefore, the architecture of the laser chip supports an optoelectronic solution for optical connectors used in AI-driven data centers, with good reliability and cost efficiency, that is adaptive to customer preferences with a variety of configurable parameters.

In accordance with the first aspect of the present disclosure, in a manner of implementation, the selected one or more of the at least one backup semiconductor lasers replaces the selected one or more of the plurality of main semiconductor lasers in a one-to-one correspondence.

In accordance with the first aspect of the present disclosure, in a manner of implementation, the laser chip further includes at least one backup laser drivers that is configured for driving the at least one backup semiconductor lasers respectively, and, the at least one selector is further configured for selecting one or more of the at least one backup laser drivers associated with the selected one or more of the at least one backup semiconductor lasers, such that the selected one or more of the at least one backup laser drivers drives the selected one or more of the at least one backup semiconductor lasers for providing the one or more backup optical signals.

In accordance with the first aspect of the present disclosure, in a manner of implementation, a total number of the at least one backup semiconductor lasers is 100% of a total number of the plurality of main semiconductor lasers, and, the plurality of main semiconductor lasers are coupled to a plurality of main optic fiber cables respectively.

In accordance with the first aspect of the present disclosure, in a manner of implementation, the at least one backup semiconductor lasers is coupled to at least one backup optic fiber cables respectively. The laser chip is deployed on a transmitting end, and, digital routing operations are performed on the transmitting end and a receiving end associated with the transmitting end, such that data transmission via the selected one or more of the plurality of main semiconductor lasers and one or more of the plurality of main optic fiber cables associated with the selected one or more of the plurality of main semiconductor lasers is replaced by data transmission via the selected one or more of the at least one backup semiconductor lasers and one or more of the plurality of backup optic fiber cables associated with the selected one or more of the at least one backup semiconductor lasers.

In accordance with the first aspect of the present disclosure, in a manner of implementation, the at least one backup semiconductor lasers is paired with the plurality of main semiconductor lasers in a one-to-one correspondence, and, a respective backup semiconductor laser, that is representative of each of the at least one backup semiconductor lasers, is coupled to a respective main optic fiber cable out of the plurality of main optic fiber cables. A respective main semiconductor laser paired with the respective backup semiconductor laser is also coupled to the respective main optic fiber cable.

In accordance with the first aspect of the present disclosure, in a manner of implementation, a total number of the at least one backup semiconductor lasers is a ratio of a total number of the plurality of main semiconductor lasers, and, the plurality of main semiconductor lasers are coupled to a plurality of main optic fiber cables respectively. The ratio is less than 100%.

In accordance with the first aspect of the present disclosure, in a manner of implementation, the ratio is between 10% and 20%.

In accordance with the first aspect of the present disclosure, in a manner of implementation, the at least one backup semiconductor lasers is coupled to at least one backup optic fiber cables respectively, the laser chip is deployed on a transmitting end, and, digital routing operations are performed on the transmitting end and a receiving end associated with the transmitting end, such that data transmission via the selected one or more of the plurality of main semiconductor lasers and one or more of the plurality of main optic fiber cables associated with the selected one or more of the plurality of main semiconductor lasers is replaced by data transmission via the selected one or more of the at least one backup semiconductor lasers and one or more of the plurality of backup optic fiber cables associated with the selected one or more of the at least one backup semiconductor lasers.

In accordance with the first aspect of the present disclosure, in a manner of implementation, the plurality of main semiconductor lasers is divided into a plurality of groups, and, the at least one backup semiconductor lasers are assigned to the plurality of groups. A respective backup semiconductor laser, that is representative of each of the at least one backup semiconductor lasers, is optically routed to be coupled to a respective main optic fiber cable out of the plurality of main optic fiber cables. A respective main semiconductor laser of a respective group out of the plurality of groups is coupled to the respective main optic fiber cable, the respective backup semiconductor laser is assigned to the respective group, the respective main semiconductor laser is from the selected one or more of the plurality of main semiconductor lasers.

In accordance with the first aspect of the present disclosure, in a manner of implementation, the respective backup semiconductor laser is optically routed to be coupled to the respective main optic fiber by an optical router, and, the optical router includes an optical mirror and an optical switch.

In accordance with the first aspect of the present disclosure, in a manner of implementation, the plurality of main laser drivers are interposed between the at least one selector and the plurality of main semiconductor lasers, and, the at least one backup laser drivers are interposed between the at least one selector and the at least one backup semiconductor lasers.

In accordance with the first aspect of the present disclosure, in a manner of implementation, the laser chip further includes at least one secondary backup semiconductor lasers, that is configured for replacing malfunctioning backup semiconductor lasers out of the at least one backup semiconductor lasers.

In accordance with the first aspect of the present disclosure, in a manner of implementation, the at least one selector is interposed between the plurality of main laser drivers and the plurality of main semiconductor lasers, and, the at least one selector is interposed between the plurality of main laser drivers and the at least one backup semiconductor lasers. The at least one selector is further configured for selecting one or more of the plurality of main laser drivers associated with the selected one or more of the plurality of main semiconductor lasers, such that the selected one or more of the plurality of main laser drivers drives the selected one or more of the at least one backup semiconductor lasers for providing the one or more backup optical signals.

In accordance with the first aspect of the present disclosure, in a manner of implementation, a total number of the at least one backup semiconductor lasers is 100% of a total number of the plurality of main semiconductor lasers, and, the plurality of main semiconductor lasers are coupled to a plurality of main optic fiber cables respectively.

In accordance with the first aspect of the present disclosure, in a manner of implementation, the at least one backup semiconductor lasers is paired with the plurality of main semiconductor lasers in a one-to-one correspondence, and, a respective backup semiconductor laser, that is representative of each of the at least one backup semiconductor lasers, is coupled to a respective main optic fiber cable out of the plurality of main optic fiber cables. A respective main semiconductor laser paired with the respective backup semiconductor laser is also coupled to the respective main optic fiber cable.

In accordance with the first aspect of the present disclosure, in a manner of implementation, the at least one selector includes a plurality of 1-to-2 multiplexers, a respective 1-to-2 multiplexer out of the plurality of 1-to-2 multiplexers is connected to a respective main laser driver out of the plurality of main laser drivers that drives the respective main semiconductor laser, the respective 1-to-2 multiplexer is also connected to the respective main semiconductor laser and the respective backup semiconductor.

In accordance with the first aspect of the present disclosure, in a manner of implementation, the plurality of main semiconductor lasers are Vertical-Cavity Surface-Emitting Lasers (VCSELs), Edge-Emitting Lasers (EELs), or, Light-Emitting Diodes (LEDs), and, the laser chip is incorporated into an optical transceiver.

In accordance with a second aspect, the present disclosure provides a selector of an optical transceiver. The optical transceiver includes: a plurality of main laser drivers, configured for providing a plurality of pulsed currents; a plurality of main semiconductor lasers, configured for providing a plurality of main optical signals in response to the plurality of pulsed currents respectively; and at least one backup semiconductor lasers. The at least one selector is configured for selecting one or more of the plurality of main semiconductor lasers, and, selecting one or more of the at least one backup semiconductor lasers to replace the selected one or more of the plurality of main semiconductor lasers, such that the selected one or more of the at least one backup semiconductor lasers provides one or more backup optical signals that serves to replace one or more of the plurality of main optical signals associated with the selected one or more of the plurality of main semiconductor lasers.

With reference to the second aspect, the architecture and selection mechanism of the optical transceiver provides an optoelectronic solution for optical connectors used in AI-driven data centers, with good reliability and cost efficiency. The architecture of the optical transceiver provides several aspects for parametrization of the optical transceiver for optimization, including the level of redundancy, i.e., the number of the backup semiconductor lasers relative to the number of main semiconductor lasers, the implementation details of the at least one selector, the placement of the selectors before or after the laser drivers, the installment of additional optic fiber cables. As such, the architecture of the optical transceiver provides several aspects for parametrization, for configuring the optical transceiver to reach a well balance among different factors like system stability, cost efficiency, system bandwidth, cost sensitivity, and circuit area. Therefore, the architecture of the optical transceiver supports an optoelectronic solution for optical connectors used in AI-driven data centers, with good reliability and cost efficiency, that is adaptive to customer preferences with a variety of configurable parameters.

In accordance with a third aspect, the present disclosure provides a method for managing multiple laser channels. The method includes: providing a plurality of pulsed currents by a plurality of main laser drivers; providing a plurality of main optical signals in response to the plurality of pulsed currents by a plurality of main semiconductor lasers respectively; and using at least one selector for selecting one or more of the plurality of main semiconductor lasers, and, selecting one or more of at least one backup semiconductor lasers to replace the selected one or more of the plurality of main semiconductor lasers, such that the selected one or more of the at least one backup semiconductor lasers provides one or more backup optical signals that serves to replace one or more of the plurality of main optical signals associated with the selected one or more of the plurality of main semiconductor lasers.

With reference to the third aspect, the method supports an optoelectronic solution for optical connectors used in AI-driven data centers, with good reliability and cost efficiency, that is adaptive to customer preferences with a variety of configurable parameters.

### BRIEF DESCRIPTION OF THE DRAWINGS

The drawings are provided to illustrate example embodiments described herein and are not intended to limit the scope of the present disclosure.

FIG. 1 is a schematic diagram illustrating a GPU array surrounded by four VCSEL arrays.

FIG. 2 is a schematic diagram illustrating a laser chip according to some embodiments.

FIG. 3 is a schematic diagram illustrating a first setting of the laser ship according to some embodiments.

FIG. 4 is a schematic diagram illustrating a second setting of the laser ship according to some embodiments.

FIG. 5 is a schematic diagram illustrating a third setting of the laser ship according to some embodiments.

FIG. 6 is a schematic diagram illustrating a fourth setting of the laser ship according to some embodiments.

FIG. 7 is a schematic diagram illustrating a fifth setting of the laser ship according to some embodiments.

FIG. 8 is a schematic diagram illustrating a sixth setting of the laser ship according to some embodiments.

FIG. 9 is a schematic diagram illustrating a seventh setting of the laser ship according to some embodiments.

FIG. 10 is a schematic diagram illustrating an eighth setting of the laser ship according to some embodiments.

FIG. 11 is a schematic diagram illustrating a ninth setting of the laser ship according to some embodiments.

FIG. 12 is a schematic diagram illustrating an optical transceiver according to some embodiments.

FIG. 13 is a flow chart illustrating a method for managing multiple laser channels according to some embodiments.

FIG. 14 is a schematic diagram illustrating a VCSEL chip suitable for high-speed data transmission according to some embodiments.

### DETAILED DESCRIPTION

Aspects and embodiments of the present invention will now be discussed with reference to the accompanying figures. Further aspects and embodiments will be apparent to those skilled in the art. All documents mentioned in this text are incorporated herein by reference.

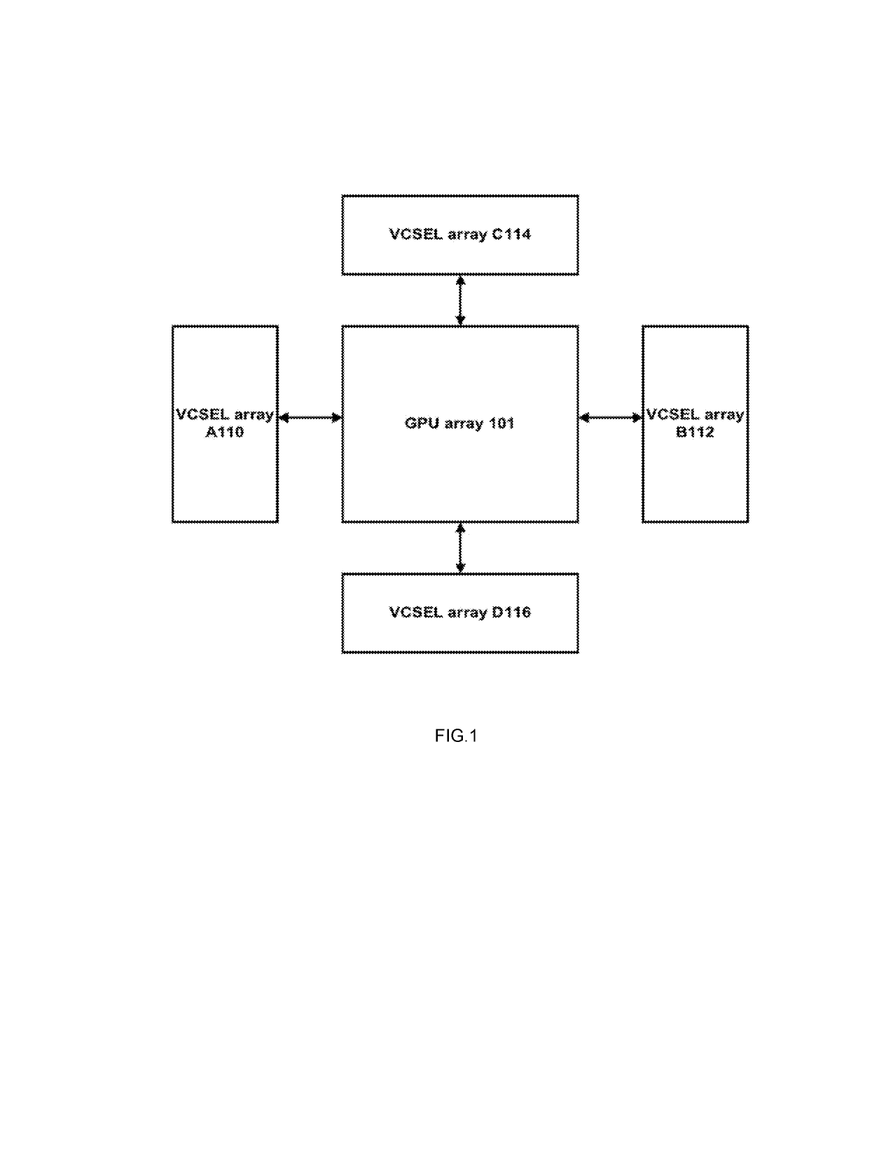

Referring to FIG. 1, FIG. 1 is a schematic diagram illustrating a GPU array surrounded by four VCSEL arrays. A GPU array 101 is surrounded by four VCSEL arrays from four different directions, including a VCSEL array A110, a VCSEL array B112, a VCSEL array C114, and a VCSEL array D116. The GPU array 101 has a number of graphics processing units (GPUs). GPUs are widely used in Artificial intelligence (AI) infrastructures, such as AI-driven data centers for processing AI workloads. Within a data center, with the development of AI models such as large-language-model (LLM), AI applications require higher data rate like 400 gigabytes (GB), 800 GB, and even 1.6 terabytes (TB). Optical interconnects are introduced to help increase data throughput and reduce latency, so as to meet the demands of intra-data center networks of AI-driven data centers. An optical transceiver allows the interconversion of optical and electrical signals during the data transmission, and may be deployed as components for transmission, reception, laser chips, photodetector chips, and other internal components for optical interconnects in an AI-driven data center. At the transmitting end (TX), the optical transceiver converts electrical signals into optical signals that are sent via fiber optic medium, and then optical signals are transformed back into electrical signals at the receiving end (RX). Optical transceivers are widely adopted to create high-speed optical connectors, for connecting GPUs, central processing units (CPUs), and storage networks. Typically, an optical transceiver has a number of semiconductor lasers, such as Vertical-Cavity Surface-Emitting Lasers (VCSELs). A number of VCSELs may form VCSEL arrays that surround a GPU from different directions with bundles of fibers routed from TX to RX, and this provides an optical solution with cost efficiency. As shown in FIG. 1, the GPU array 101 is surrounded by four VCSEL arrays from four different directions, and the four VCSEL arrays together with optic fibers provide important optical connection to the GPU array 101 for data transmission. The GPU array 101 may be replaced by a CPU array, or a storage network, or any specialized circuits, module, or sub-system. A VCSEL array is usually placed next to the GPU array 101 to enjoy benefits of short connection distance and improved data transmission, and the GPU array 101 with surrounding VCSEL arrays may be highly integrated. A VCSEL array itself may be incorporated into a bigger chip, such as a part of an optical transceiver. VCSELs may be replaced by other types of semiconductor lasers, such as Edge-Emitting Lasers (EELs) and Light-Emitting Diodes (LEDs). AI-driven data centers have demands for higher bandwidth, faster speeds, lower latency, scalability for handling increased data volumes, energy efficiency and cost efficiency. Therefore, devices and components based on optoelectronic technologies are introduced to AI-driven data centers for handling the extreme AI workloads with respect to processing and routing, and this requires using semiconductor lasers such as VCSELs to establish reliable and high-speed optical connections to various devices and components, like GPUs, CPUs, and storage network. However, because semiconductor lasers, in most practical situations, are distributed densely, one semiconductor laser may be only 50 micrometers away from each other, and the whole semiconductor array is usually placed next to the device or component that receives optical signals sent by the semiconductor array via fiber optic medium, therefore, it is difficult or impractical to replace a single semiconductor laser that malfunctions or has its performance downgraded below an acceptable threshold level. As such, laser reliability, such as VCSEL reliability, becomes a serious concern that may affect system performance because a laser (such as a VCSEL, an EEL, or a LED) may have its performance deteriorating due to high temperature caused by transceiver heat and other reasons like moisture corrosion. Because the semiconductor laser array and the whole laser chip may be highly integrated or incorporated into a bigger chip, it is not possible to detach a laser chip out and plug a new laser chip back in, and therefore it is not feasible to try to replace a semiconductor laser that malfunctions or has deteriorating performance once manufactured. In consideration of the intense usage of optical transceivers and semiconductor lasers like VCSELs for optical connectors and data transmission, and also in consideration of the high temperature environment inside a data center, one semiconductor laser such as a VCSEL has a small chance of malfunctioning or has its performance downgraded below an acceptable level. While a single VCSEL may have only 1% chance of burning out (caused by high temperature, moisture corrosion or other reasons), however, for a VCSEL array like 10 by 10 VCSELs, the chance of the VCSEL array having at least one VCSEL that burns out is significantly larger. Also, as the number of VCSELs used in a VCSEL array increases to cope with increased demands for bandwidth and data rate, the chance of malfunctioning or performance deterioration by the VCSEL array as a whole may increase to nearly 100%. And it is not possible to precisely predict which VCSEL out of the VCSEL array has the highest chance of burning out, and, the particular VCSEL that burns out and causes data transmission error may be switching among different VCSELs during the usage of the VCSEL array, such unstable performance may be caused by changes of working temperatures, changes of working voltages, and different processing corners for manufacturing VCSELs. As such, AI-driven data centers and other implementations where enormous amounts of data must be processed, routed, and stored by using optical connectors formed of semiconductor lasers, have demands for an optoelectronic solution for optical connectors with good reliability and cost efficiency.

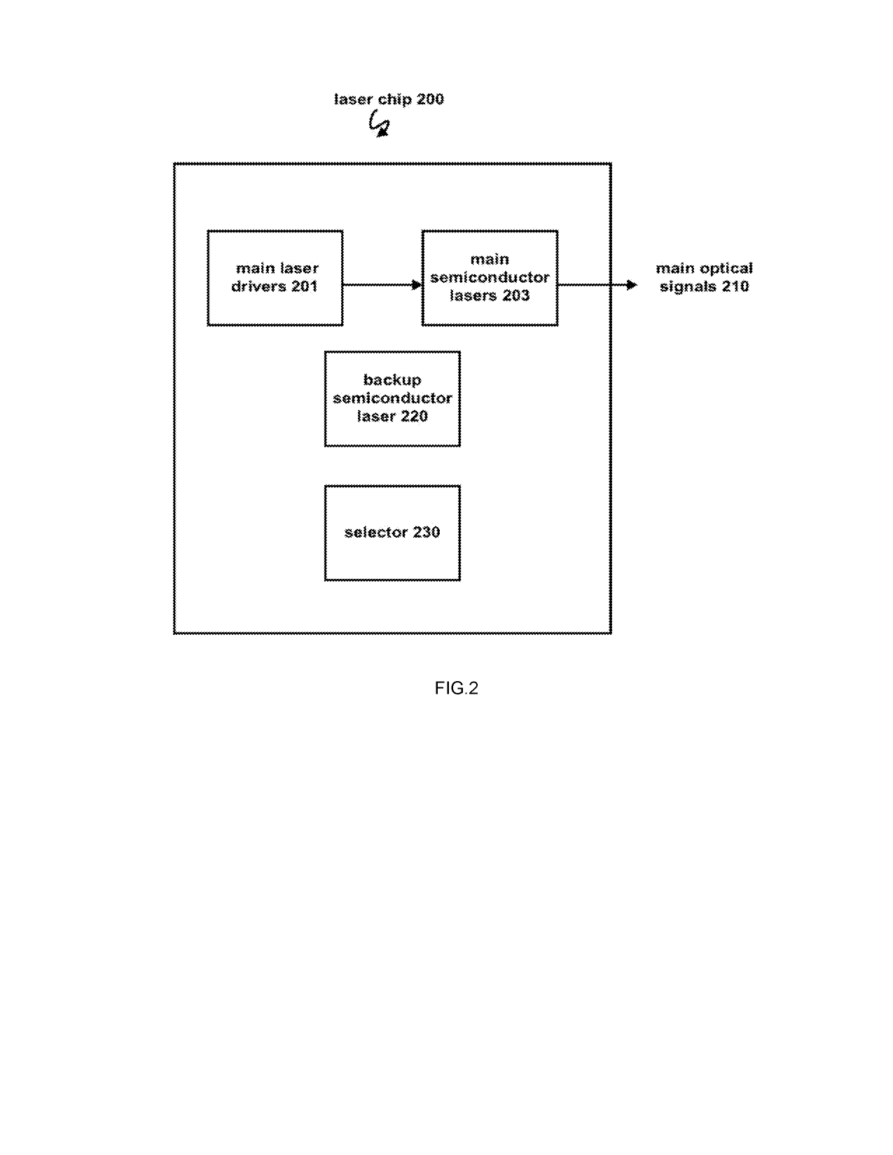

Referring to FIG. 2, FIG. 2 is a schematic diagram illustrating a laser chip according to some embodiments. As shown in FIG. 2, the laser chip 200 includes main laser drivers 201, main semiconductor lasers 203, a backup semiconductor laser 220, and a selector 230. Here, the laser chip 200 includes at least one backup semiconductor lasers that is represented by the backup semiconductor laser 220, and at least one selector that is represented by the selector 230. The main laser drivers 201 represent a plurality of main laser drivers, configured for providing a plurality of pulsed currents. The main semiconductor lasers 203 represent a plurality of main semiconductor lasers, configured for providing a plurality of main optical signals (indicated as main optical signals 210) in response to the plurality of pulsed currents respectively. The at least one selector of the laser chip 200 is configured for selecting one or more of the plurality of main semiconductor lasers, and, selecting one or more of the at least one backup semiconductor lasers to replace the selected one or more of the plurality of main semiconductor lasers, such that the selected one or more of the at least one backup semiconductor lasers provides one or more backup optical signals that serves to replace one or more of the plurality of main optical signals associated with the selected one or more of the plurality of main semiconductor lasers. As such, the laser chip 200 uses at least one backup semiconductor lasers that is represented by the backup semiconductor laser 220, to provide a certain level of redundancy with respect to the main semiconductor lasers 203. Also, the plurality of main semiconductor lasers 201 are Vertical-Cavity Surface-Emitting Lasers (VCSELs), Edge-Emitting Lasers (EELs), or, Light-Emitting Diodes (LEDs). And, the laser chip 200 may be incorporated into an optical transceiver. As mentioned above, AI applications might require a data rate as high as 224 GB or even higher. VCSELs that form a VCSEL array of an optical transceiver that operates with a data rate of 224 GB or higher might be faced with unreliable VCSELs. In most situations, at least one VCSEL may have performance problems like burning out, performance deteriorating, or malfunctioning, and the whole VCSEL array may have data transmission error consequentially. Also, the laser driver for driving a semiconductor laser may be implemented in a variety of ways, such as using a power switch transistor for generating a pulsed current for driving the semiconductor laser.

Still referring to FIG. 2, the selector 230, that represents at least one selector of the laser chip 200, is configured for selecting one or more of the plurality of main semiconductor lasers. The standard for selecting a main semiconductor laser out of the plurality of main semiconductor lasers may be determined based on evaluation of the performance of each VCSEL. When any VCSEL burns out, has performance downgraded below an acceptable threshold, or malfunctions, such VCSEL may be selected. The standard for selecting may be adjusted by changing the configuration of the laser chip 200 or by firmware updating, and this allows calibration of the laser chip 200 with respect to its capabilities of identifying unreliable main semiconductor lasers and replacing identified unreliable main semiconductor lasers with backup semiconductor lasers, even if the laser chip 200 is highly integrated or incorporated into a bigger chip. Further, the standard for selecting may have a certain level of preventiveness. In addition to identifying a main semiconductor laser as unreliable by evaluating its performance with respect to an acceptable threshold, the selector 230 may identify a particular main semiconductor laser as unreliable preventively when there is evidence that the particular main semiconductor is becoming more and more likely to be unreliable, i.e., a tendency of increasing chance of burning out. For example, an acceptable threshold may be used to determine whether a particular main semiconductor laser has burned out, and another preventive threshold may be used to determine whether there is an increasing chance that the particular main semiconductor will burn out. By introducing both a safeguard against malfunctioning lasers and a preventive precaution against lasers having an increasing chance of malfunctioning into the standard for selecting a main semiconductor laser out of the plurality of main semiconductor lasers, the laser chip 200 not only replaces an unreliable main semiconductor laser with a selected backup semiconductor laser, but also preventively replaces a main semiconductor laser having an increasing chance of becoming unreliable with a selected backup semiconductor laser. The standard for selecting one or more of the plurality of main semiconductor lasers by the at least one selector is customizable and is optionally available for updating during the usage of the laser chip 200, by firmware downloading or parameter setting. This allows the laser chip 200 to have a good adaptability to various customer needs with respect to their sensitivity to unreliable semiconductor lasers. For example, an AI-driven data center may rely on reliable VCSELs to provide optical connections with GPUs and storage network, and therefore may prefer a higher acceptable threshold for telling whether a VCSEL is unreliable, and may further impose a preventive precaution by checking on VCSELs that show a tendency of increasing chance of malfunctioning. If a scoring mechanism is used to evaluate a VCSEL's performance, a score lower than 60 means that the VCSEL has burn out or malfunction, then a score lower than 80 means that the VCSEL has triggered a preventive warning. Then, by counting the times of preventive warnings triggered by the same VCSEL during a time period, or by other statistical algorithms, one may calculate a tendency of this VCSEL's chance of burning out. For customers who would like to spend more on redundant resources in exchange for better system stability, the laser chip 200 and the at least one selector may provide a safeguard for selecting and replacing unreliable main semiconductor lasers with backup semiconductor lasers, and also provide, by customer choice, a preventive precaution for preventively identifying and replacing main semiconductor lasers that do not trigger the safeguard yet but show a tendency of increasing chance of burning out.

Still referring to FIG. 2, the at least one backup semiconductor lasers serve as a pool of reserved laser resources for replacing unreliable main semiconductor lasers. For example, the laser chip 200 may have 10 by 10 main semiconductor lasers 203, and 20 backup semiconductor lasers represented by the backup semiconductor laser 220. Therefore, the laser chip 200 is expected to have a total number of 100 semiconductor lasers that are available for operating. The data transmission via the laser chip 200 might not require a maximized usage of all of the 100 semiconductor lasers, but the laser chip 200 by design is supposed to be capable of offering 100 semiconductor lasers that are operating at the same time for optical connection. As such, when one or more of the 10 by 10 main semiconductor lasers 203 is identified as unreliable (may be determined by a suitable standard, or by a preventive mechanism), one or more of the backup semiconductor lasers is selected to replace the unreliable main semiconductor lasers, such that the laser chip 200 still keeps its capability of offering up to 100 lasers to operate at the same time. In this regard, the laser chip 200, by using at least one backup semiconductor lasers that is represented by the backup semiconductor laser 220, to provide a certain level of redundancy with respect to the main semiconductor lasers 203, is capable of maintaining a designed number of semiconductor lasers that are available for operating at the same time and are reliable by a customizable standard. This also means that the main optical signals 210 as output by the laser chip 200 remain stable, because the selected one or more of the at least one backup semiconductor lasers provides one or more backup optical signals that serves to replace one or more of the plurality of main optical signals associated with the selected one or more of the plurality of main semiconductor lasers. Also, because the laser chip 200 uses the at least one selector to select unreliable main semiconductor lasers to be replaced by backup semiconductor lasers, which all happen within the laser chip 200, therefore, the RX side that is supposed to receive optical signals from the laser chip 200 and the pre-stage circuits that are supposed to send digital signals to the laser chip 200, are capable of maintaining normal data transmission, unaffected by the internal operations within the laser chip 200. In this regard, the laser chip 200, such as an optical transceiver having a VCSEL array, has established a built-in self-adjusting mechanism that may routinely identify and replace unreliable semiconductor lasers with reliable semiconductor lasers internally, and therefore maintains a steady and good-quality output. The improved system-level stability comes at the cost of additional backup semiconductor lasers and additional circuit area consequentially. In consideration of the intense usage of optical transceivers and semiconductor lasers like VCSELs for optical connectors and data transmission, and also in consideration of the expected long life span of a laser chip for forming optical connections with GPUs, CPUs, and storage networks, the redundant lasers and additional costs are well warranted, because it is practically impossible to replace a single malfunctioning VCSEL out of an optical transceiver whose data transmission as a whole could be jeopardized by this single malfunctioning VCSEL.

Still referring to FIG. 2, main optical signals 210 may be transmitted via fiber optic medium such as optic fiber cables to the post-stage circuits with respect to the laser chip 200, such as a GPU array. The selected one or more of the at least one backup semiconductor lasers provides one or more backup optical signals that serves to replace one or more of the plurality of main optical signals 210 associated with the selected one or more of the plurality of main semiconductor lasers 203. As such, the laser chip 200 is capable of handling all kinds of possible situations, that include none of the main optical signals 210 is replaced, only one of the main optical signals 210 is replaced, or all of the main optical signals 210 are replaced. The level of redundancy, that is determined by the number of backup semiconductor lasers 200 relative to the number of main semiconductor lasers 203, determines a maximum ratio of main semiconductor lasers 203 that are replaced by backup semiconductor lasers, as well as a maximum ratio of main optical signals 210 that are replaced by backup optical signals. A level of redundancy at 100% means that there are exactly the same number of backup semiconductor lasers represented by the backup semiconductor laser 220 as the main semiconductor lasers 203. And when the laser chip 200 has 10 by 10 main semiconductor lasers 203 and 20 backup semiconductor lasers, the level of redundancy is set at 20%. Ideally, the level of redundancy is set at 100%, and this means for each main semiconductor laser, there is a corresponding backup semiconductor laser that may be selected for replacement if the main semiconductor laser burns out. However, as the data volumes rapidly increases, the number of main semiconductor lasers also rapidly increases and may reach hundreds or even thousands in magnitude, and the level of redundancy set at 100% requires an equal number of backup semiconductor lasers as compared to the number of main semiconductor lasers, and therefore, the total hardware resources and circuit area must consequentially increase. In this regard, a balance between redundancy and costs may be reached, and one may set the level of redundancy somewhere between 10% to 20%. Depending on customer's preferences, the level of redundancy may be set at any suitable value, like 100%, or, from 10% to 20%. Also, the number of main semiconductor lasers 201 of the laser chip 200 may be any value depending on the design requirements, like a 10 by 10 VCSEL array that has 100 VCSELs. The architecture of the laser chip 200 has a good adaptiveness with respect to the number of semiconductor lasers that are needed to form optical connections as well as the level of redundancy for replacing unreliable semiconductor lasers so as to maintain the optical connections stable.

Still referring to FIG. 2, the at least one selector of the laser chip, represented by the selector 230, may have a variety of means of implementation. In some embodiments, the at least one selector is a plurality of 1-to-2 multiplexers (MUX). Each MUX has one input and two outputs, so each MUX can select which output out of the two outputs receives the input. When the level of redundancy is set at 100%, each main semiconductor laser is paired with one backup semiconductor laser respectively, and a pair of main semiconductor laser and respective backup semiconductor laser receive the two outputs from a corresponding MUX, and this MUX receives the input from the corresponding main laser driver. Therefore, as the 1-to-2 MUX is interposed between the main laser driver and the pair of main semiconductor laser and respective backup semiconductor laser, the pulsed current generated by the main laser driver may be routed to be sent to either the main semiconductor laser or the backup semiconductor laser. As such, the plurality of 1-to-2 MUXs may be used for selecting one or more of the plurality of main semiconductor lasers, and, selecting one or more of the at least one backup semiconductor lasers to replace the selected one or more of the plurality of main semiconductor lasers, such that the selected one or more of the at least one backup semiconductor lasers provides one or more backup optical signals that serves to replace one or more of the plurality of main optical signals associated with the selected one or more of the plurality of main semiconductor lasers. The at least one selector may be implemented as multiplexers, addressing units, or other types of circuits, modules, firmware, or hardware. For example, the at least one selector may be implemented as an addressing module that determines whether each main semiconductor laser receives the respective pulsed current for generating a main optical signal, and also determines whether each backup semiconductor laser receives the respective pulsed current for generating a backup optical signal. A bit map may be used to tell whether each main semiconductor laser is reliable and therefore the at least one selector may use the bit map to quickly select unreliable main semiconductor lasers.

Still referring to FIG. 2, the at least one selector may be placed before or after the laser drivers. Take using MUXs as the selectors for example, a plurality of MUXs may be placed before the main laser drivers 201, and therefore the laser chip 200 would also need backup laser drivers for driving the backup semiconductor lasers. The plurality of MUXs receive digital signals for controlling the laser drivers as inputs, and selectively send the digital signals to the main laser drivers for driving the main semiconductor lasers or the backup laser drivers for driving the backup semiconductor lasers respectively, therefore establishing a selection mechanism between main semiconductor lasers and backup semiconductor lasers. Placing the at least one selector before the laser drivers would require additional backup laser drivers, but this type of setting has the benefits of reduced impedance because the laser driver is coupled to the semiconductor laser directly. Alternatively, the plurality of MUXs may be placed after the main laser drivers 201, and the plurality of MUXs receive pulsed currents from the main laser drivers 201 as inputs, and selectively send the pulsed currents to the main semiconductor lasers or the backup semiconductor lasers respectively, therefore establishing a selection mechanism between the main semiconductor lasers and the backup semiconductor lasers. Placing the at least one selector after the laser drivers could reuse the main laser drivers for driving the backup semiconductor lasers and therefore saves the costs of additional backup laser drivers, but this type of setting introduces the selectors into the calculation of impedance, because the laser driver is first coupled to the selector, like a MUX, that is connected to both the main semiconductor laser and the backup semiconductor laser. As a result, placing a selector after laser drivers may affect system bandwidth, and this may be diminished by adding a source follower to the source terminal of the laser driver, thereby reducing the impact of the impedance of the selector and the semiconductor laser on the system bandwidth. The setting of placing the selectors before the laser drivers and the setting of placing the selectors after the laser drivers have their own pros and cons respectively. The architecture of the laser chip 200 supports both settings, and provides adaptiveness to various customer preferences.

Still referring to FIG. 2, the architecture of laser chip 200 is adaptive to a change of the number of main optical signals 210 that is usually determined by the customer needs, such as the optical connectors needed for a GPU array, or the data transmission specifications as required by a storage network. Once the number of main optical signals 210 is determined, or in other words, the number of optical outputs from the laser chip 200 is determined, then, the internal details and structure of the laser chip 200 may be optimized to be adapted to customer preferences. With the number of optical outputs determined, the architecture of laser chip 200 provides several aspects for parametrization of the laser chip 200 for optimization. For example, the number of main semiconductor lasers 203 is designed to be equal to the number of optical outputs by the laser chip 200, and the level of redundancy, i.e., the number of the backup semiconductor lasers relative to the number of main semiconductor lasers 203, may be an adjustable parameter for manufacturing the laser chip 200. The level of redundancy may be set to 100%, or 10%, or 20% or other values for determining how many backup semiconductor lasers are installed in the laser chip 200. For another example, the implementation details of the at least one selector of the laser chip 200 are also parametrized. The selectors may be implemented as a plurality of 1-to-2 MUXs, or other types of MUXs like 2-to-4 or 4-to-6. The selectors also may be implemented as a general addressing module that applies address coding to the main semiconductor lasers and the backup semiconductor lasers of the laser chip 200 such that it may use addressing functions to conveniently select between the main semiconductor lasers and the backup semiconductor lasers. For another example, the placement of the selectors before or after the laser drivers is also parametrized, and each setting has its own pros and cons. For another example, the installment of additional optic fiber cables is also parametrized. The main optical signals 210 are transmitted via main optic fiber cables that are coupled to post-stage circuits like a GPU array. The backup semiconductor lasers that are selected to replace unreliable main semiconductor lasers may reuse the main optic fiber cables, but this might require optical coupling or optical routing. Alternatively, the backup semiconductor lasers may have their own backup optic fiber cables and save the troubles of optical routing, and instead, digital routing which is simpler and faster than optical routing is needed. Accordingly, the architecture of the laser chip 200 provides several aspects for parametrization, for configuring the laser chip 200 to reach a well balance among different factors like system stability, cost efficiency, system bandwidth, cost sensitivity, and circuit area. Therefore, the architecture of the laser chip 200 supports an optoelectronic solution for optical connectors used in AI-driven data centers, with good reliability and cost efficiency, that is adaptive to customer preferences with a variety of configurable parameters.

Referring to FIG. 1 and FIG. 2, laser chips that include a number of semiconductor lasers, such as an optical transceiver that includes a VCSEL array, are widely used in AI-infrastructures like AI-driven data centers for establishing optical connections with various electrical modules, chips, or subsystems, such as GPU array, CPUs, and storage network. A laser chip converts electrical signals into optical signals that are sent via fiber optic medium, such as optic fiber cables. Because laser chips are usually placed next to other electrical modules and incorporated into a bigger chip, it is practically impossible to detach or isolate an unreliable semiconductor laser such as a VCSEL out of a laser chip. To solve the problems of unreliable semiconductor lasers like VCSELs, especially when the data rate is 224 GB or higher, the present disclosure provides an architecture of a laser chip, such as an optical transceiver that includes a number of MUXs and multiple VCSEL channels. By providing VCSEL sparing or VCSEL redundancy, in case a VCSEL burns out, the laser chip may turn off the VCSEL that burns out and turn on another VCSEL channel, and the MUX serves as a selector that realizes the switch of the data transmission from the VCSEL that burns out to another VCSEL that is turned on instead. As a tradeoff between MUX resistance and die-area, the MUX as a selector may be deployed at the VCSEL itself, either before the VCSEL driver, or after the VCSEL driver. In cases that the MUX as a selector is deployed after the VCSEL driver, the MUX resistance might increase the resistance and affect the system bandwidth. To counter the MUX resistance, the VCSEL driver may be improved with an emitter follower or a source follower. The rationale for improving the VCSEL driver is to drive the VCSEL with an emitter follower if the VCSEL is based on SiGe such as a NPN, or, to drive the VCSEL with a source follower if the VCSEL is a Complementary Metal Oxide Semiconductor (CMOS) such as a NMOS. The low impedance of the emitter follower or the source follower helps to diminish the impact of the VCSEL impedance over the modulation bandwidth, and the linearity is largely set by the emitter follower resistance or the source follower resistance, and therefore is not affected by the VCSEL resistance, which is usually high as 75 Ohms or 150 Ohms.

In summary, the architecture and selection mechanism of the laser chip 200 provide an optoelectronic solution for optical connectors used in AI-driven data centers, with good reliability and cost efficiency. The architecture of the laser chip 200 provides several aspects for parametrization of the laser chip 200 for optimization, including the level of redundancy, i.e., the number of the backup semiconductor lasers relative to the number of main semiconductor lasers 203, the implementation details of the at least one selector, the placement of the selectors before or after the laser drivers, the installment of additional optic fiber cables. As such, the architecture of the laser chip 200 provides several aspects for parametrization, for configuring the laser chip 200 to reach a well balance among different factors like system stability, cost efficiency, system bandwidth, cost sensitiveness, and circuit area. Therefore, the architecture of the laser chip 200 supports an optoelectronic solution for optical connectors used in AI-driven data centers, with good reliability and cost efficiency, that is adaptive to customer preferences with a variety of configurable parameters.

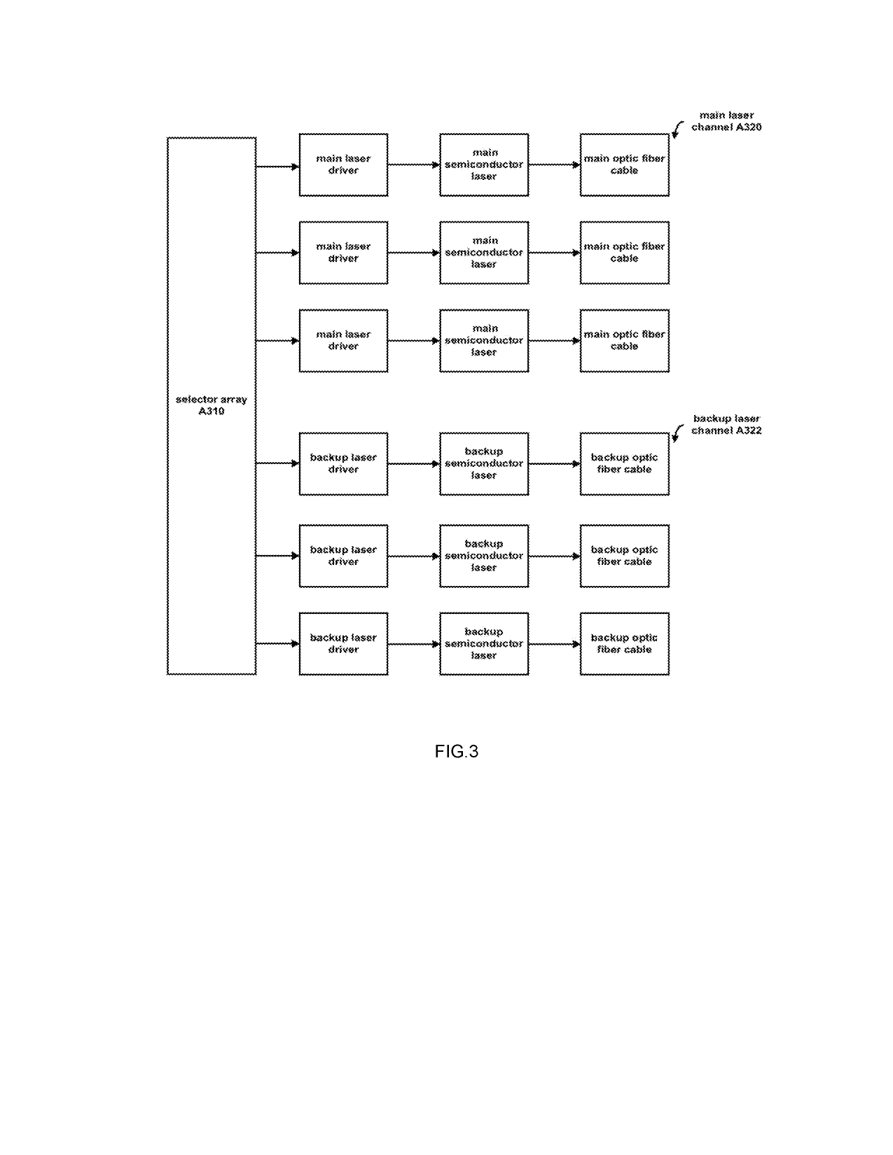

Referring to FIGS. 3 through 11, these are schematic diagrams that illustrate a number of settings of the laser chip. These settings vary on a variety of aspects, such as the internal connecting relationships of the laser chip, and several aspects for parametrization that may be adjusted for configuring the laser chip. These aspects for parametrization include the level of redundancy, i.e., the number of the backup semiconductor lasers relative to the number of main semiconductor lasers, the implementation details of the at least one selector, the placement of the selectors before or after the laser drivers, and the installment of additional optic fiber cables. The configurable parameters allow the architecture chip to be adaptive to customer preferences, after the number of optical outputs is determined. Generally, the number of main semiconductor lasers is designed to be equal to the number of optical outputs by the laser chip, and there are also an equal number of main laser drivers for driving the main semiconductor lasers. Detailed embodiments will be described below with reference to FIGS. 3 through 11 for illustrating how the architecture of the laser chip might be adapted by configuration of parameters to meet various preferences. It is noted that the exact number of components shown in the figures are merely illustrative, and there are embodiments of the present disclosure that might have fewer, more or equal number of components of the figures. Also, some figures of FIGS. 3 through 11 use a selector array to refer to the at least one selector of the laser chip. A selector array may be considered to include a number of selectors, such a number of MUXs, or, a selector array may be considered to be a single selector such as an addressing module, unless expressly indicated by the figures otherwise.

Referring to FIG. 3, FIG. 3 is a schematic diagram illustrating a first setting of the laser ship according to some embodiments. The selector array A310 is placed before the laser drivers, and there are three main laser drivers, three main semiconductor lasers, three main optic fiber cables, which form multiple main laser channels, such as the main laser channel A320. There are also three backup laser drivers, three backup semiconductor lasers, and three backup optic fiber cables, which form multiple backup laser channels, such as the backup laser channel A322. As such, the level of redundancy, i.e., the number of the backup semiconductor lasers relative to the number of main semiconductor lasers, is set at 100%. Also, the implementation details of the at least one selector may be implemented as several MUXs or addressing units for the selection between three main laser drivers and three backup laser drivers. The placement of the selectors before the laser drivers means that additional backup laser drivers are needed, but this type of setting has the benefits of reduced impedance because the laser driver is coupled to the semiconductor laser directly. Also, the installment of additional optic fiber cables means that the backup semiconductor lasers may have their own backup optic fiber cables and saves the troubles of optical routing, and instead, digital routing which is simpler and faster than optical routing is needed. For example, if the main semiconductor laser of the main laser channel A320 is identified as unreliable and therefore selected to be replaced by the backup semiconductor laser of the backup laser channel A322. Then, the main optical signal associated with the main semiconductor laser of the main laser channel A320 is replaced by a backup optical signal provided by the backup semiconductor laser of the backup laser channel A322. As such, digital routing operations are performed on the transmitting end, i.e., the laser chip, and on the receiving end, such as a GPU array that is optically connected with the laser chip, such that data transmission via the selected one or more of the plurality of main semiconductor lasers and one or more of the plurality of main optic fiber cables associated with the selected one or more of the plurality of main semiconductor lasers is replaced by data transmission via the selected one or more of the at least one backup semiconductor lasers and one or more of the plurality of backup optic fiber cables associated with the selected one or more of the at least one backup semiconductor lasers. For example, data transmission via the main laser channel A320 is replaced by data transmission via the backup laser channel A322. And because such digital routing operations are performed in the digital domain, there is no involvement of optical routing and therefore does not involve complicated optical components. The setting as shown in FIG. 3, requires additional backup laser drivers and additional backup optic fiber cables as additional resources, provides the highest level of redundancy at 100%, requires only digital routing operations on both TX and RX to make a laser channel switch, and also has improved system bandwidth and reduced impedance.

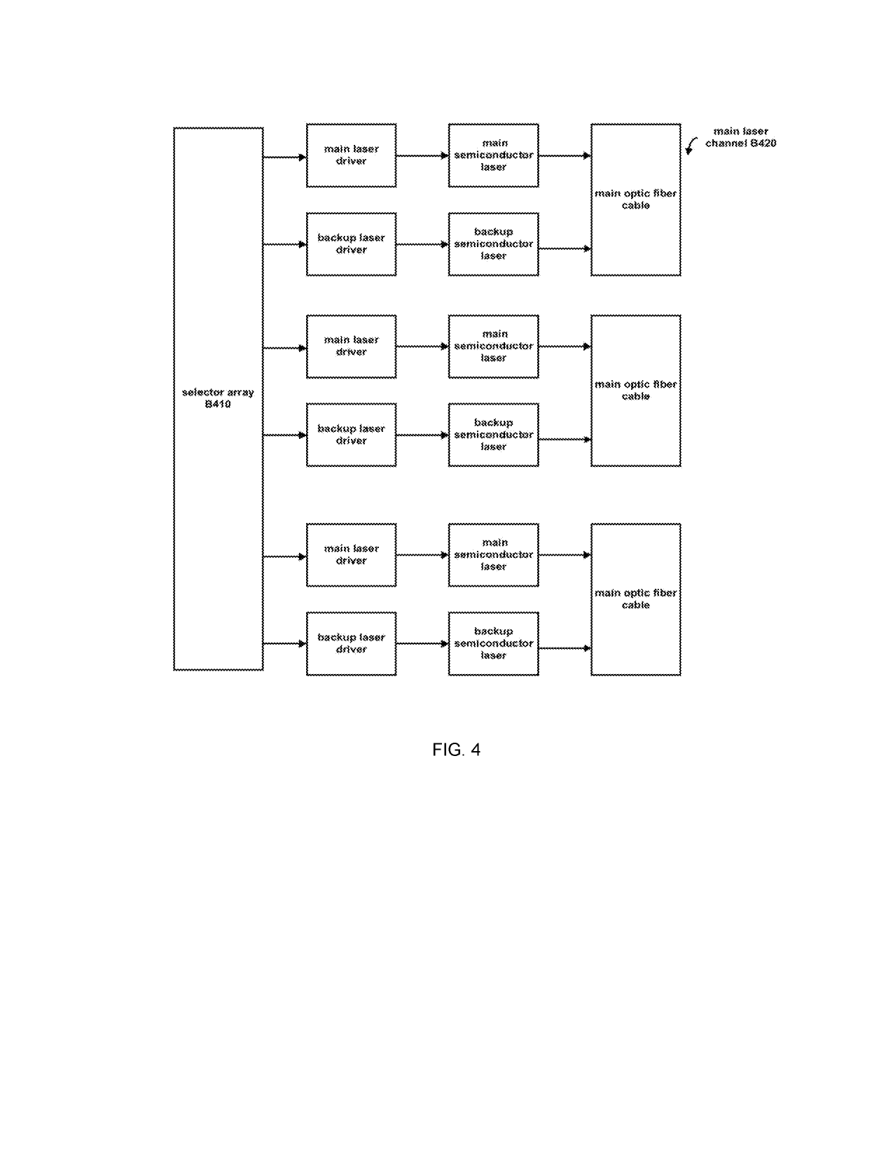

Referring to FIG. 4, FIG. 4 is a schematic diagram illustrating a second setting of the laser ship according to some embodiments. The selector array B410 is placed before the laser drivers, and there are three main laser drivers, three main semiconductor lasers, three main optic fiber cables, which form multiple main laser channels, such as the main laser channel B420. There are also three backup laser drivers, three backup semiconductor lasers, and no additional backup optic fiber cables. The backup semiconductor lasers are coupled to the main optic fiber cables to reuse the main optic fiber cables. As such, the level of redundancy, i.e., the number of the backup semiconductor lasers relative to the number of main semiconductor lasers, is set at 100%. Also, the implementation details of the at least one selector may be implemented as several MUXs or addressing units for the selection between three main laser drivers and three backup laser drivers. The placement of the selectors before the laser drivers means that additional backup laser drivers are needed, but this type of setting has the benefits of reduced impedance because the laser driver is coupled to the semiconductor laser directly. Also, by reusing the main optic fiber cables, it saves additional costs for the installment of additional optic fiber cables. For example, if the main semiconductor laser of the main laser channel B420 is identified as unreliable and therefore selected to be replaced by the backup semiconductor laser that is also coupled to the main optic fiber cable of the main laser channel B420. Then, the main optical signal associated with the main semiconductor laser of the main laser channel B420 is replaced by a backup optical signal provided by the backup semiconductor laser that is also coupled to the main optic fiber cable of the main laser channel B420. As such, this setting does not require any digital routing operations to be performed on the receiving end, such as a GPU array that is optically connected with the laser chip, because data transmission via the selected one or more of the plurality of main semiconductor lasers and one or more of the plurality of main optic fiber cables associated with the selected one or more of the plurality of main semiconductor lasers still goes through the same main optic fiber cable. For example, data transmission via the main laser channel B420, whether by the main semiconductor laser or the backup semiconductor laser, goes through the same main optic fiber cable. Also, because each main semiconductor laser is paired with a backup semiconductor laser and a pair of main semiconductor laser and backup semiconductor laser are coupled to the same optic fiber cable, this means that two semiconductor lasers are coupled to one optic fiber cable. Therefore, there is no need for digital routing operations to be performed on the transmitting end, i.e., the laser chip. The setting as shown in FIG. 4, requires additional backup laser drivers as additional resources, provides the highest level of redundancy at 100%, does not require digital routing operations on either TX or RX, instead uses a laser switch between a pair of main semiconductor laser and backup semiconductor laser that are coupled to the same main optic fiber cable, and also have improved system bandwidth and reduced impedance.

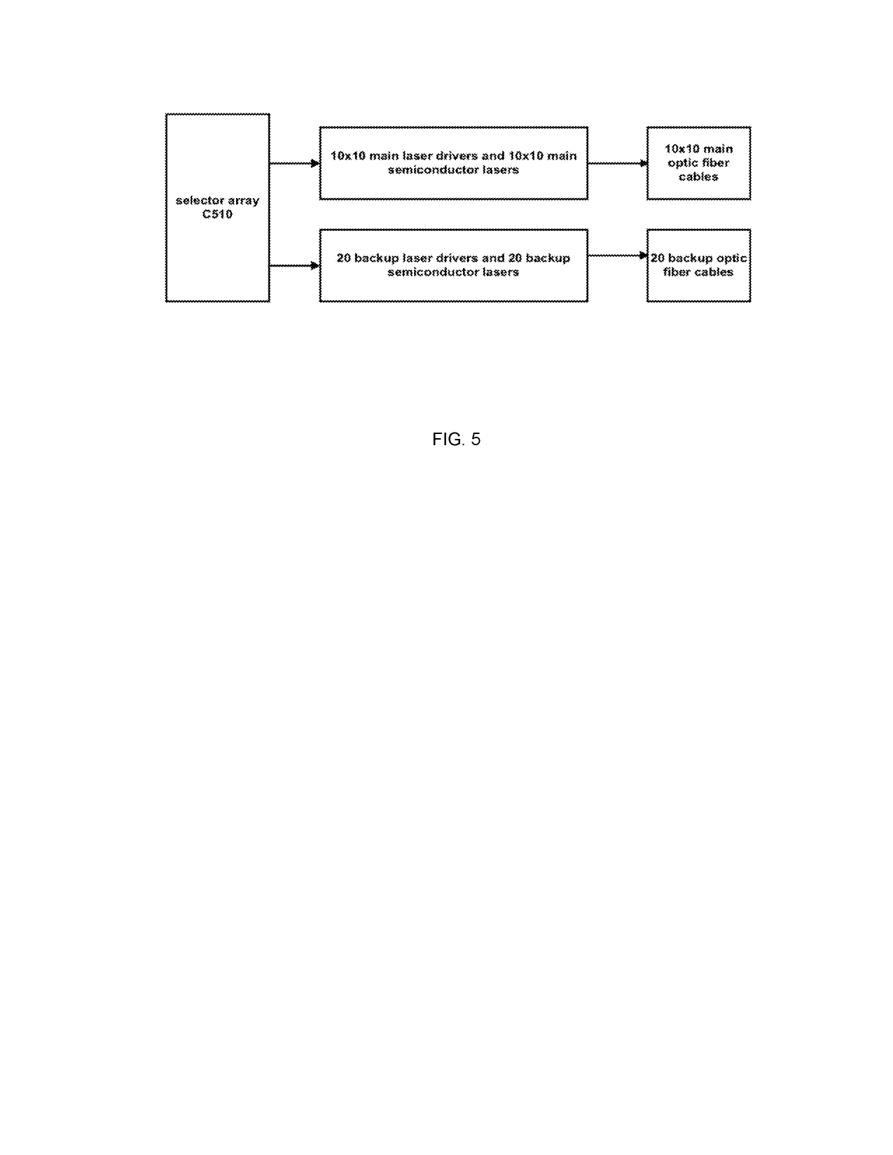

Referring to FIG. 5, FIG. 5 is a schematic diagram illustrating a third setting of the laser ship according to some embodiments. The selector array C510 is placed before the laser drivers, and there are 10x10 main laser drivers, 10x10 main semiconductor lasers, 10x10 main optic fiber cables, which form multiple main laser channels. There are also 20 backup laser drivers, 20 backup semiconductor lasers, and 20 backup optic fiber cables, which form multiple backup laser channels. The setting of FIG. 5 is similar to the setting of FIG. 3, and varies on the level of redundancy, i.e., the number of the backup semiconductor lasers relative to the number of main semiconductor lasers, which is set at 100% in FIG. 3 and 20% in FIG. 5. Also, the implementation details of the at least one selector may be implemented as several MUXs or addressing units for the selection between three main laser drivers and three backup laser drivers. The placement of the selectors before the laser drivers means that additional backup laser drivers are needed, but this type of setting has the benefits of reduced impedance because the laser driver is coupled to the semiconductor laser directly. Also, the installment of additional optic fiber cables means that the backup semiconductor lasers may have their own backup optic fiber cables and saves the trouble of optical routing, and instead, digital routing which is simpler and faster than optical routing is needed. As such, digital routing operations are performed on the transmitting end, i.e., the laser chip, and on the receiving end, such as a GPU array that is optically connected with the laser chip, such that data transmission via the selected one or more of the plurality of main semiconductor lasers and one or more of the plurality of main optic fiber cables associated with the selected one or more of the plurality of main semiconductor lasers is replaced by data transmission via the selected one or more of the at least one backup semiconductor lasers and one or more of the plurality of backup optic fiber cables associated with the selected one or more of the at least one backup semiconductor lasers. And because such digital routing operations are performed in the digital domain, there is no involvement of optical routing and therefore does not involve complicated optical components. The setting as shown in FIG. 5, requires additional backup laser drivers and additional backup optic fiber cables as additional resources, provides the a certain level of redundancy at 20%, requires only digital routing operations on both TX and RX to make a laser channel switch, and also have improved system bandwidth and reduced impedance. Referring to FIG. 3 and FIG. 5, it is noted that, the level of redundancy, i.e., the number of the backup semiconductor lasers relative to the number of main semiconductor lasers, is adjustable, and may be adjusted to cope with preferences. Ideally, the level of redundancy is set at 100%, and this means for each main semiconductor laser, there is a corresponding backup semiconductor laser that may be selected for replacement if the main semiconductor laser burns out. However, as the data volumes rapidly increase, the number of main semiconductor lasers also rapidly increases and may reach hundreds or even thousands in magnitude, and the level of redundancy set at 100% requires an equal number of backup semiconductor lasers as compared to the number of main semiconductor lasers, and therefore, the total hardware resources and circuit area must consequentially increase. In this regard, a balance between redundancy and costs may be reached, and one may set the level of redundancy somewhere between 10% to 20%. Depending on customer's preferences, the level of redundancy may be set at any suitable value, like 100%, or, from 10% to 20%.

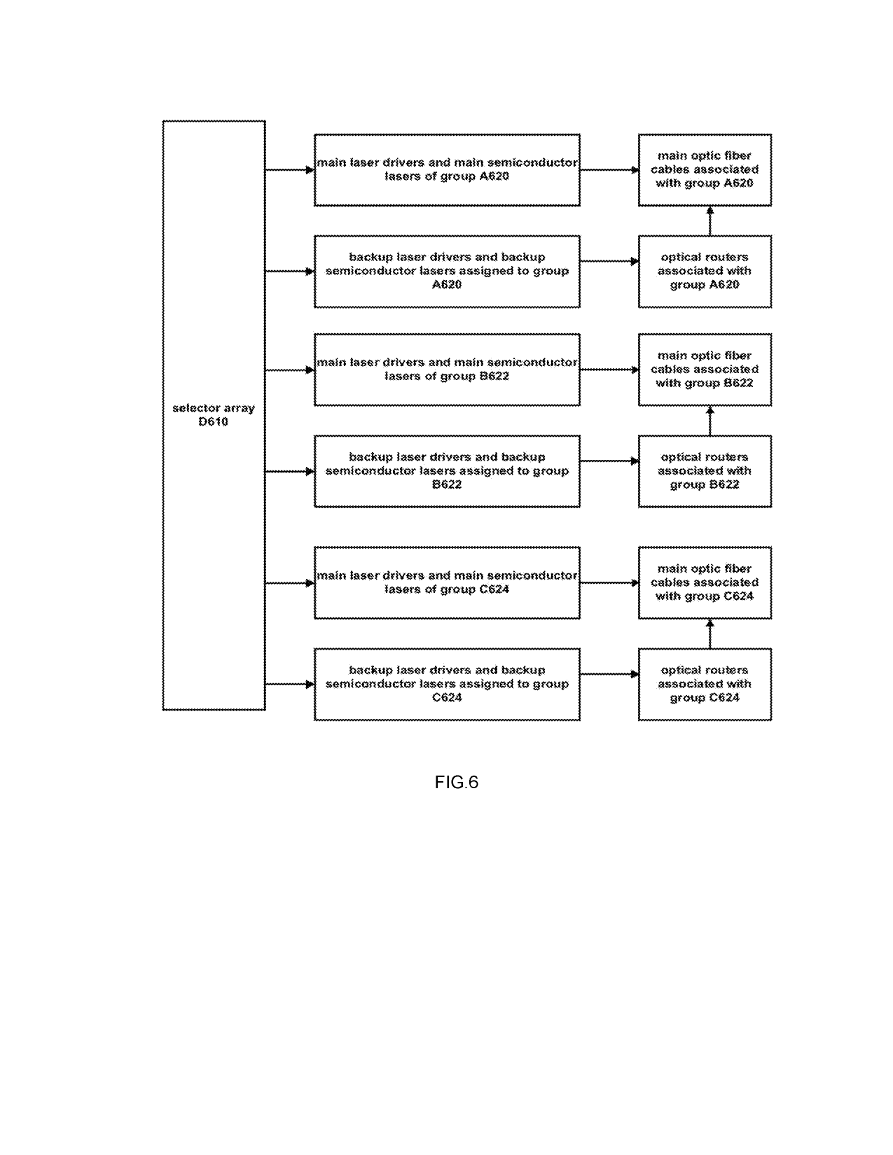

Referring to FIG. 6, FIG. 6 is a schematic diagram illustrating a fourth setting of the laser ship according to some embodiments. The selector array D610 is placed before the laser drivers. There are a number of main laser drivers, a number of main semiconductor lasers, and a number of main optic fiber cables. There are also a number of backup laser drivers and a number of backup semiconductor lasers, but no additional backup optic fiber cables. As mentioned above regarding the setting of FIG. 4, the level of redundancy is set at 100%, each main semiconductor laser is paired with a backup semiconductor laser, and a pair of main semiconductor laser and backup semiconductor laser are coupled to the same optic fiber cable. The setting of FIG. 4 does not require digital routing operations on either TX or RX, instead uses a laser switch between a pair of main semiconductor laser and backup semiconductor laser that are coupled to the same main optic fiber cable, and this necessitates the highest level of redundancy at 100%. Because it is hard to predict which main semiconductor laser may become unstable and warrant a replacement, the backup semiconductor lasers must be able to replace the unstable main semiconductor laser and support the data transmission. However, if the level of redundancy is not set at 100%, then there will be more main semiconductor lasers than backup semiconductor lasers, such as the setting of FIG. 5 that has a level of redundancy set at 20%. If additional backup optic fiber cables are provided, such as the settings of FIG. 3 and FIG. 5, then selected backup semiconductor lasers may provide optical outputs through their own backup optic fiber cables, and the RX side may apply the digital routing operations to switch the data transmission to the proper backup optic fiber cables. However, in some implementations where additional backup optic fibers are not available, the selected backup semiconductor lasers must reuse the main optic fiber cables, and this means that the optical outputs from the selected backup semiconductor lasers must be routed to the main optic fiber cables associated with the unstable main semiconductor lasers. In this regard, one backup semiconductor laser may have its optical outputs to be routed to more than one main optic fiber cables, because there are more main semiconductor lasers than backup semiconductor lasers. The involvement of optical routing operations, adds complexity to the system design, and causes enlarged die-area. In order to counter the challenges, the setting of FIG. 6 divides the main semiconductor lasers into several groups, and assigns backup semiconductor lasers to each group. So the optical routing operations are limited to between main semiconductor lasers and backup semiconductor lasers within the same group, and this also simplifies the optical routers that are used to complete the optical routing operations. As shown in FIG. 6, optical routers associated with group A620 are used to perform optical routing operations between main laser drivers and main semiconductor lasers of group A620 and backup laser drivers and backup semiconductor lasers assigned to group A620, which share main optic fiber cables associated with group A620. Similarly, optical routers associated with group B622 are used to perform optical routing operations between main laser drivers and main semiconductor lasers of group B622 and backup laser drivers and backup semiconductor lasers assigned to group B622, which share main optic fiber cables associated with group B622. Also, optical routers associated with group C624 are used to perform optical routing operations between main laser drivers and main semiconductor lasers of group C624 and backup laser drivers and backup semiconductor lasers assigned to group C624, which share main optic fiber cables associated with group C624. A fixed number of semiconductor lasers in each group are operating, and whenever a main semiconductor laser malfunctions, a backup semiconductor laser is selected to replace the main semiconductor laser. By dividing the main semiconductor lasers into groups, and assigning each group one or more backup semiconductor lasers, this helps to quickly identify the malfunctioning semiconductor laser. Further, since each backup semiconductor laser is responsible for only a fixed number of main semiconductor lasers within the same group, the backup semiconductor laser may be routed to be coupled to any of the several main optic fiber cables in the same group. This means that the optical routing operations are performed only on the RX side, and the TX side is not aware of the routing and merely receives optical signals from the several main optic fiber cables of the same group. The size of each group may be well calibrated to make sure that one backup semiconductor laser is not routed to too many main optic fiber cables, such as limited to 1 to 3, or 1 to 5. The optical routing operations may be performed by optical mirror, optical switch, and other components that are used in an optical network. The setting of FIG. 6 is useful in that it does not require any involvement by the RX side, and this does save a lot of complexity by preventing the malfunction troubles from spreading to the RX side, or the downstream modules. The RX side is required to be involved only if the RX side has to change the expected optic fiber cables for receiving the data. Here, by dividing the main semiconductor lasers into groups, it becomes economically practicable to add some optical components, such as the optical routers, on the TX side to allow the backup semiconductor laser's output, if selected, to be coupled to a selected main optic fiber cable, so that the malfunctioning main semiconductor laser corresponding to the selected main optic fiber cable may be shut down. The setting of FIG. 6 is also useful in that it does not require any additional backup optic fiber cables and may work with a level of redundancy lower than 100%, thereby making it adaptive to certain preferences.

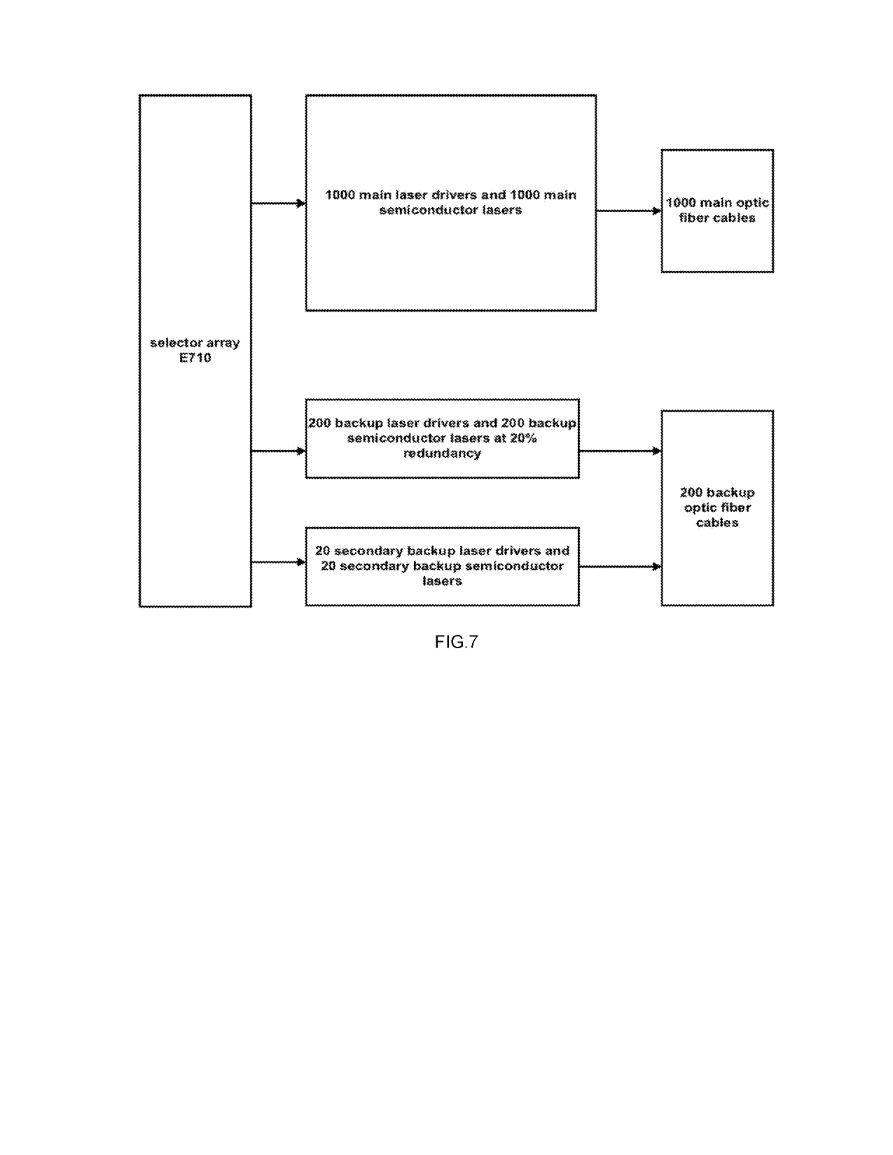

Referring to FIG. 7, FIG. 7 is a schematic diagram illustrating a fifth setting of the laser ship according to some embodiments. The selector array E710 is placed before the laser drivers. There are 1000 main laser drivers and 1000 main semiconductor lasers, and 1000 main optic fiber cables. There are also 200 backup laser drivers and 200 backup semiconductor lasers at 20% redundancy, and 200 backup optic fiber cables. As such, the level of redundancy, i.e., the number of the backup semiconductor lasers relative to the number of main semiconductor lasers, is set at 20%. It is noted that, because the number of main semiconductor lasers is as high as 1000, which might become a mainstream standard given the rapidly increasing data volume, even with a redundancy level at 20%, there are still 200 backup semiconductor lasers. As such, with a base number of 200, the backup semiconductor lasers themselves might impose a significant chance of burning out. Accordingly, the setting of FIG. 7 introduces 20 secondary backup laser drivers and 20 secondary backup semiconductor lasers, which provides a secondary redundancy level at 10%, with respect to 200 backup semiconductor lasers, and therefore provides a secondary level of safeguards against laser burning out.

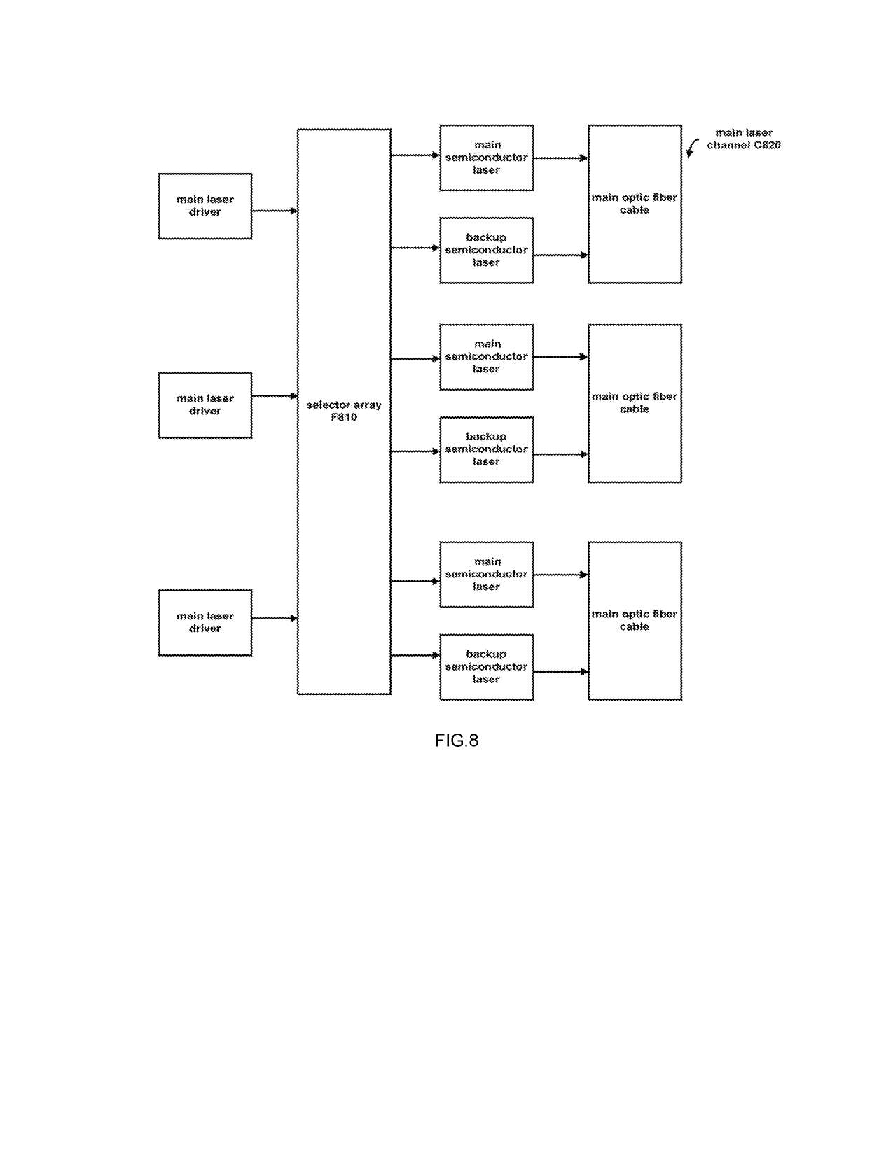

Referring to FIG. 8, FIG. 8 is a schematic diagram illustrating a sixth setting of the laser ship according to some embodiments. The selector array F810 is placed after the laser drivers, and there are three main laser drivers, three main semiconductor lasers, three main optic fiber cables, which form multiple main laser channels, such as the main laser channel C820. There are also three backup semiconductor lasers, and no additional backup laser drivers or additional backup optic fiber cables. The backup semiconductor lasers are coupled to the main optic fiber cables to reuse the main optic fiber cables. As such, the level of redundancy, i.e., the number of the backup semiconductor lasers relative to the number of main semiconductor lasers, is set at 100%. Also, the implementation details of the at least one selector may be implemented as several MUXs or addressing units for the selection between three main laser drivers and three backup laser drivers. The placement of the selectors after the laser drivers means that there is no need for additional backup laser drivers, but this type of setting might have increased impedance, which may be diminished by adding a source follower to the source terminal of the laser driver. Also, by reusing the main optic fiber cables, it saves additional costs for the installment of additional optic fiber cables. For example, if the main semiconductor laser of the main laser channel C820 is identified as unreliable and therefore selected to be replaced by the backup semiconductor laser that is also coupled to the main optic fiber cable of the main laser channel C820. Then, the main optical signal associated with the main semiconductor laser of the main laser channel C820 is replaced by a backup optical signal provided by the backup semiconductor laser that is also coupled to the main optic fiber cable of the main laser channel C820. As such, this setting does not require any digital routing operations to be performed on the receiving end, such as a GPU array that is optically connected with the laser chip, because data transmission via the selected one or more of the plurality of main semiconductor lasers and one or more of the plurality of main optic fiber cables associated with the selected one or more of the plurality of main semiconductor lasers still goes through the same main optic fiber cable. For example, data transmission via the main laser channel C820, whether by the main semiconductor laser or the backup semiconductor laser, goes through the same main optic fiber cable. Also, because each main semiconductor laser is paired with a backup semiconductor laser and a pair of main semiconductor laser and backup semiconductor laser are coupled to the same optic fiber cable, this means that two semiconductor lasers are coupled to one optic fiber cable. Therefore, there is no need for digital routing operations to be performed on the transmitting end, i.e., the laser chip. The setting as shown in FIG. 8, does not require additional resources of laser drivers or backup optic fiber cables, provides the highest level of redundancy at 100%, does not require digital routing operations on either TX or RX, instead uses a laser switch between a pair of main semiconductor laser and backup semiconductor laser that are coupled to the same main optic fiber cable.

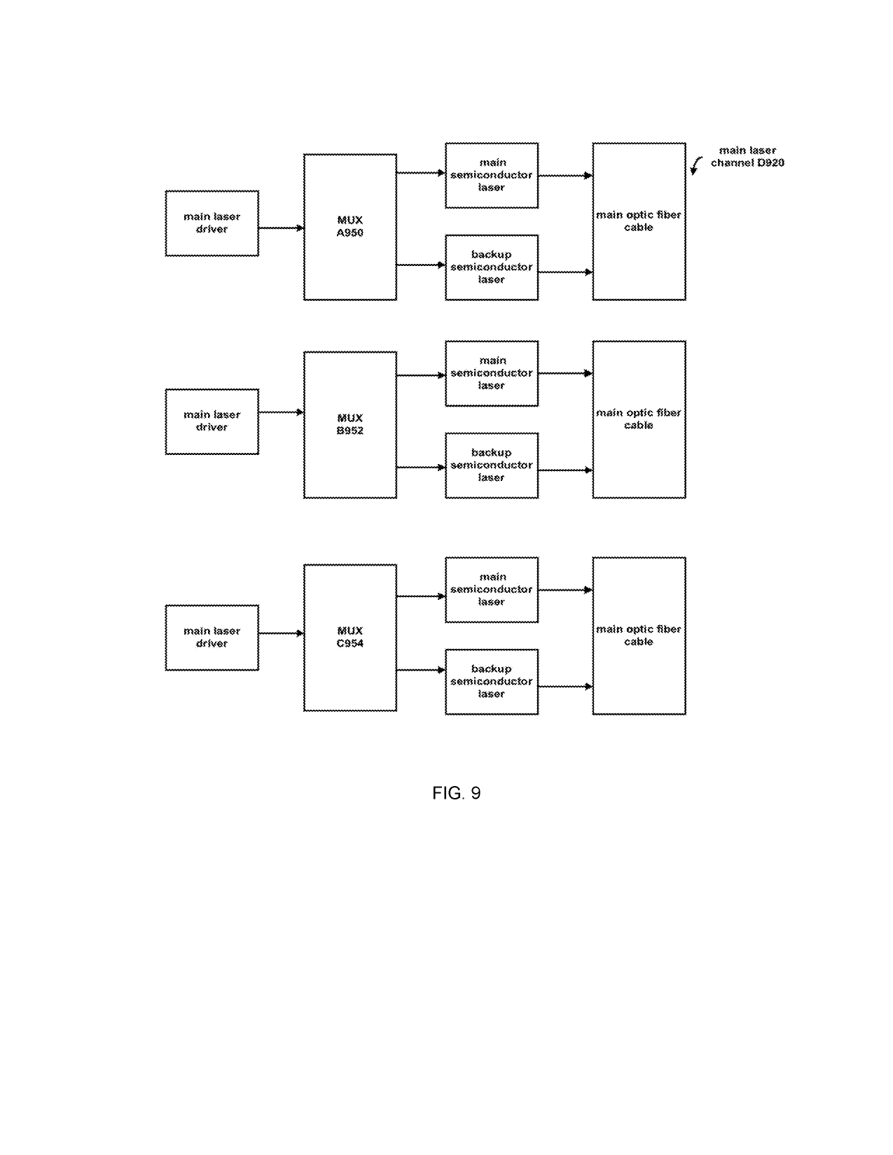

Referring to FIG. 9, FIG. 9 is a schematic diagram illustrating a seventh setting of the laser ship according to some embodiments. FIG. 9 is similar to FIG. 8, and varies in that the selector array F810 is replaced by several MUXs of FIG. 9. In FIG. 9, the three MUXs, which are MUX A950, MUX B952, and MUX C954, are placed after the laser drivers, and there are three main laser drivers, three main semiconductor lasers, three main optic fiber cables, which form multiple main laser channels, such as the main laser channel D920. There are also three backup semiconductor lasers, and no additional backup laser drivers or additional backup optic fiber cables. The backup semiconductor lasers are coupled to the main optic fiber cables to reuse the main optic fiber cables. As such, the level of redundancy, i.e., the number of the backup semiconductor lasers relative to the number of main semiconductor lasers, is set at 100%. Also, the implementation details of the at least one selector, as shown in FIG. 9, are implemented as several MUXs. In some embodiments, the several MUXs may be replaced as addressing units for the selection between three main laser drivers and three backup laser drivers. The placement of the MUXs after the laser drivers means that there is no need for additional backup laser drivers, but this type of setting might have increased impedance, which may be diminished by adding a source follower to the source terminal of the laser driver. Also, by reusing the main optic fiber cables, it saves additional costs for the installment of additional optic fiber cables. For example, if the main semiconductor laser of the main laser channel D920 is identified as unreliable and therefore selected to be replaced by the backup semiconductor laser that is also coupled to the main optic fiber cable of the main laser channel D920. Then, the main optical signal associated with the main semiconductor laser of the main laser channel D920 is replaced by a backup optical signal provided by the backup semiconductor laser that is also coupled to the main optic fiber cable of the main laser channel D920. As such, this setting does not require any digital routing operations to be performed on the receiving end, such as a GPU array that is optically connected with the laser chip, because data transmission via the selected one or more of the plurality of main semiconductor lasers and one or more of the plurality of main optic fiber cables associated with the selected one or more of the plurality of main semiconductor lasers still goes through the same main optic fiber cable. For example, data transmission via the main laser channel D920, whether by the main semiconductor laser or the backup semiconductor laser, goes through the same main optic fiber cable. Also, because each main semiconductor laser is paired with a backup semiconductor laser and a pair of main semiconductor laser and backup semiconductor laser are coupled to the same optic fiber cable, this means that two semiconductor lasers are coupled to one optic fiber cable. Therefore, there is no need for digital routing operations to be performed on the transmitting end, i.e., the laser chip. The setting as shown in FIG. 9, does not require additional resources of laser drivers or backup optic fiber cables, provides the highest level of redundancy at 100%, does not require digital routing operations on either TX or RX, instead uses a laser switch between a pair of main semiconductor laser and backup semiconductor laser that are coupled to the same main optic fiber cable.

Still referring to FIG. 9, the at least one selector is a plurality of 1-to-2 multiplexers (MUX). Each MUX has one input and two outputs, so each MUX can select which output out of the two outputs receives the input. When the level of redundancy is set at 100%, each main semiconductor laser is paired with one backup semiconductor laser respectively, and a pair of main semiconductor laser and respective backup semiconductor laser receive the two outputs from a corresponding MUX, and this MUX receives the input from the corresponding main laser driver. Therefore, as the 1-to-2 MUX is interposed between the main laser driver and the pair of main semiconductor laser and respective backup semiconductor laser, the pulsed current generated by the main laser driver may be routed to be sent to either the main semiconductor laser or the backup semiconductor laser. As such, the plurality of 1-to-2 MUXs may be used for selecting one or more of the plurality of main semiconductor lasers, and, selecting one or more of the at least one backup semiconductor lasers to replace the selected one or more of the plurality of main semiconductor lasers, such that the selected one or more of the at least one backup semiconductor lasers provides one or more backup optical signals that serves to replace one or more of the plurality of main optical signals associated with the selected one or more of the plurality of main semiconductor lasers. For example, MUX A950 serves to select the pulsed current from the main laser driver of the main laser channel D920 to be sent to the main semiconductor laser or the backup semiconductor laser of the main laser channel D920, and the selected semiconductor laser provides optical outputs to be sent via the main optic fiber cable of the main laser channel D920. As such, a mux is deployed for each pair of a main semiconductor laser and a backup semiconductor laser that shares the same main laser driver. The setting of FIG. 9 provides the highest redundancy level at 100%, and also keeps the number of main optic fiber cables unchanged, thereby preventing the involvement by the RX side.

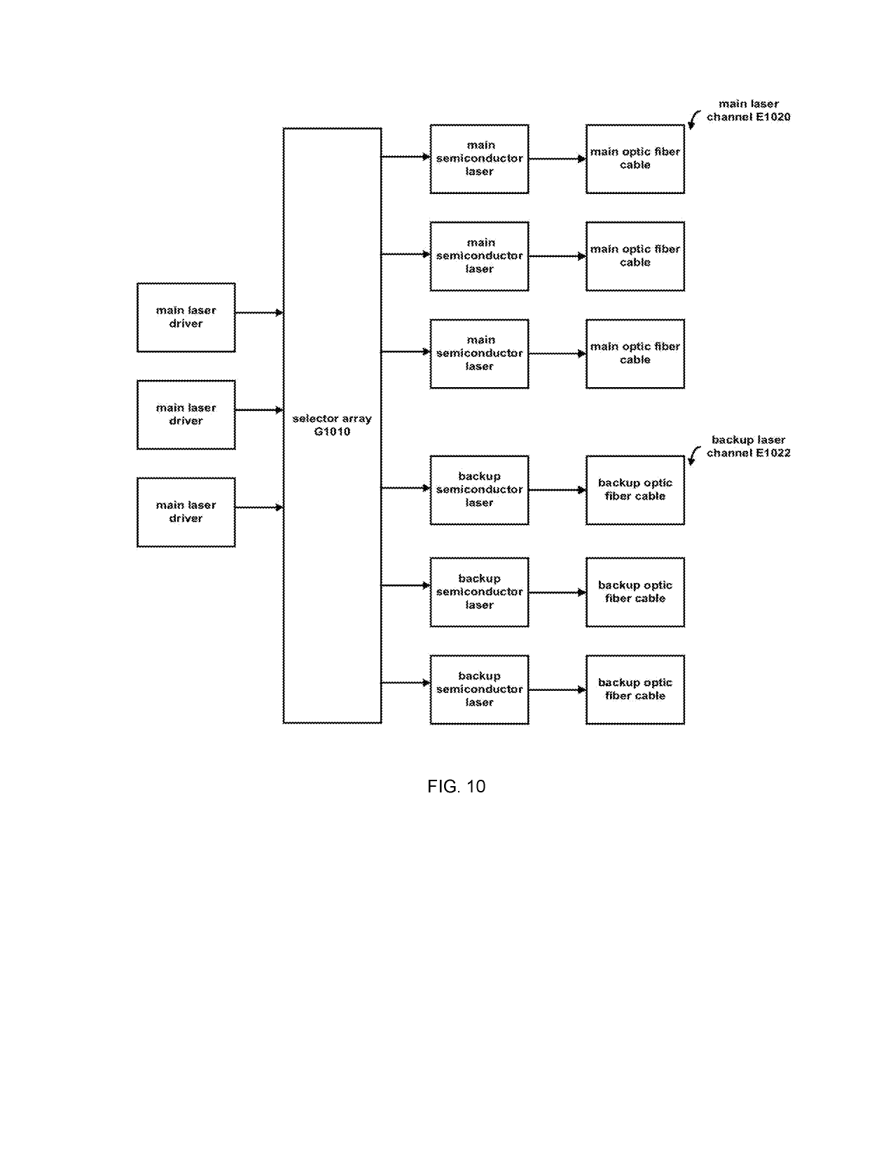

Referring to FIG. 10, FIG. 10 is a schematic diagram illustrating an eighth setting of the laser ship according to some embodiments. The selector array G1010 is placed after the laser drivers, and there are three main laser drivers, three main semiconductor lasers, three main optic fiber cables, which form multiple main laser channels, such as the main laser channel E1020. There are also no backup laser drivers, three backup semiconductor lasers, and three backup optic fiber cables, which form multiple backup laser channels, such as the backup laser channel E1022. As such, the level of redundancy, i.e., the number of the backup semiconductor lasers relative to the number of main semiconductor lasers, is set at 100%. Also, the implementation details of the at least one selector may be implemented as several MUXs or addressing units for the selection between three main laser drivers and three backup laser drivers. The placement of the selectors after the laser drivers means that there is no need for additional backup laser drivers. Also, the installment of additional optic fiber cables means that the backup semiconductor lasers may have their own backup optic fiber cables and saves the troubles of optical routing, and instead, digital routing which is simpler and faster than optical routing is needed. For example, if the main semiconductor laser of the main laser channel E1020 is identified as unreliable and therefore selected to be replaced by the backup semiconductor laser of the backup laser channel E1022. Then, the main optical signal associated with the main semiconductor laser of the main laser channel E1020 is replaced by a backup optical signal provided by the backup semiconductor laser of the backup laser channel E1022. As such, digital routing operations are performed on the transmitting end, i.e., the laser chip, and on the receiving end, such as a GPU array that is optically connected with the laser chip, such that data transmission via the selected one or more of the plurality of main semiconductor lasers and one or more of the plurality of main optic fiber cables associated with the selected one or more of the plurality of main semiconductor lasers is replaced by data transmission via the selected one or more of the at least one backup semiconductor lasers and one or more of the plurality of backup optic fiber cables associated with the selected one or more of the at least one backup semiconductor lasers. For example, data transmission via the main laser channel E1020 is replaced by data transmission via the backup laser channel E1022. And because such digital routing operations are performed in the digital domain, there is no involvement of optical routing and therefore does not involve complicated optical components. The setting as shown in FIG. 10, requires additional backup optic fiber cables as additional resources, provides the highest level of redundancy at 100%, requires only digital routing operations on both TX and RX to make a laser channel switch.

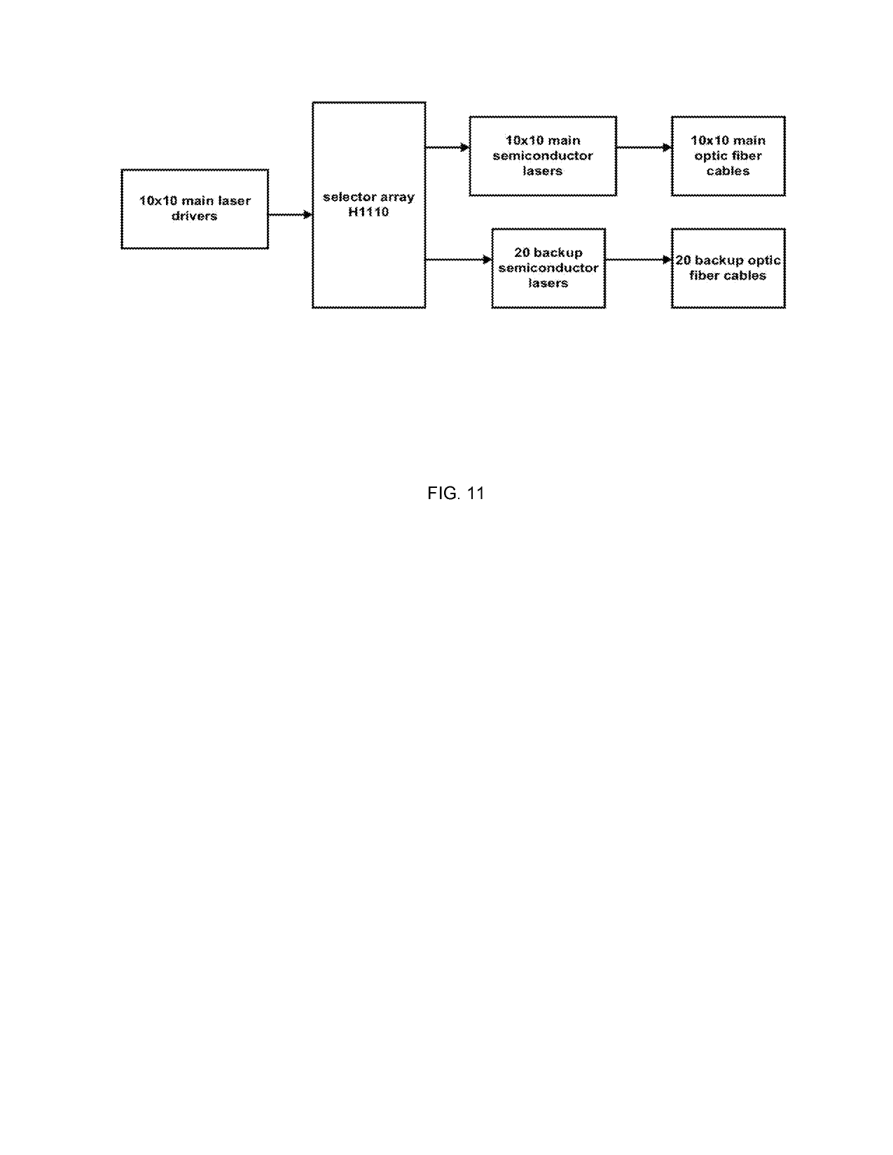

Referring to FIG. 11, FIG. 11 is a schematic diagram illustrating a ninth setting of the laser ship according to some embodiments. The selector array H1110 is placed after the laser drivers, and there are 10x10 main laser drivers, 10x10 main semiconductor lasers, 10x10 main optic fiber cables, which form multiple main laser channels. There are also no backup laser drivers, 20 backup semiconductor lasers, and 20 backup optic fiber cables, which form multiple backup laser channels. The setting of FIG. 11 is similar to the setting of FIG. 10, and varies on the level of redundancy, i.e., the number of the backup semiconductor lasers relative to the number of main semiconductor lasers, which is set at 100% in FIG. 10 and 20% in FIG. 11. Also, the implementation details of the at least one selector may be implemented as several MUXs or addressing units for the selection between three main laser drivers and three backup laser drivers. The placement of the selectors after the laser drivers means that there is no need for additional backup laser drivers. Also, the installment of additional optic fiber cables means that the backup semiconductor lasers may have their own backup optic fiber cables and saves the troubles of optical routing, and instead, digital routing which is simpler and faster than optical routing is needed. As such, digital routing operations are performed on the transmitting end, i.e., the laser chip, and on the receiving end, such as a GPU array that is optically connected with the laser chip, such that data transmission via the selected one or more of the plurality of main semiconductor lasers and one or more of the plurality of main optic fiber cables associated with the selected one or more of the plurality of main semiconductor lasers is replaced by data transmission via the selected one or more of the at least one backup semiconductor lasers and one or more of the plurality of backup optic fiber cables associated with the selected one or more of the at least one backup semiconductor lasers. And because such digital routing operations are performed in the digital domain, there is no involvement of optical routing and therefore does not involve complicated optical components. The setting as shown in FIG. 11, requires additional backup optic fiber cables as additional resources, provides the a certain level of redundancy at 20%, requires only digital routing operations on both TX and RX to make a laser channel switch, and also have improved system bandwidth and reduced impedance. Referring to FIGS. 10 and 11, it is noted that, the level of redundancy, i.e., the number of the backup semiconductor lasers relative to the number of main semiconductor lasers, is adjustable, and may be adjusted to cope with preferences. Ideally, the level of redundancy is set at 100%, and this means for each main semiconductor laser, there is a corresponding backup semiconductor laser that may be selected for replacement if the main semiconductor laser burns out. However, as the data volumes rapidly increase, the number of main semiconductor lasers also rapidly increases and may reach hundreds or even thousands in magnitude, and the level of redundancy set at 100% requires an equal number of backup semiconductor lasers as compared to the number of main semiconductor lasers, and therefore, the total hardware resources and circuit area must consequentially increase. In this regard, a balance between redundancy and costs may be reached, and one may set the level of redundancy somewhere between 10% to 20%. Depending on customer's preferences, the level of redundancy may be set at any suitable value, like 100%, or, from 10% to 20%.

Referring to FIG. 1 and FIG. 2, in some embodiments, the selected one or more of the at least one backup semiconductor lasers replaces the selected one or more of the plurality of main semiconductor lasers in a one-to-one correspondence. As such, the laser chip supports an optoelectronic solution for optical connectors used in AI-driven data centers, with good reliability and cost efficiency, that is adaptive to customer preferences with a variety of configurable parameters.

Referring to FIG. 2 and FIG. 3, in some embodiments, the laser chip further includes at least one backup laser drivers that is configured for driving the at least one backup semiconductor lasers respectively, and, the at least one selector is further configured for selecting one or more of the at least one backup laser drivers associated with the selected one or more of the at least one backup semiconductor lasers, such that the selected one or more of the at least one backup laser drivers drives the selected one or more of the at least one backup semiconductor lasers for providing the one or more backup optical signals. As such, the placement of the selectors before the laser drivers means that additional backup laser drivers are needed, but this type of setting has benefits of reduced impedance because the laser driver is coupled to the semiconductor laser directly.

Referring to FIG. 2 and FIG. 3, in some embodiments, a total number of the at least one backup semiconductor lasers is 100% of a total number of the plurality of main semiconductor lasers, and, the plurality of main semiconductor lasers are coupled to a plurality of main optic fiber cables respectively. As such, the level of redundancy, i.e., the number of the backup semiconductor lasers relative to the number of main semiconductor lasers, is set at 100%.

Referring to FIG. 2 and FIG. 3, in some embodiments, the at least one backup semiconductor lasers is coupled to at least one backup optic fiber cables respectively, the laser chip is deployed on a transmitting end, and, digital routing operations are performed on the transmitting end and a receiving end associated with the transmitting end, such that data transmission via the selected one or more of the plurality of main semiconductor lasers and one or more of the plurality of main optic fiber cables associated with the selected one or more of the plurality of main semiconductor lasers is replaced by data transmission via the selected one or more of the at least one backup semiconductor lasers and one or more of the plurality of backup optic fiber cables associated with the selected one or more of the at least one backup semiconductor lasers. As such, the laser chip requires additional backup laser drivers and additional backup optic fiber cables as additional resources, provides the highest level of redundancy at 100%, requires only digital routing operations on both TX and RX to make a laser channel switch, and also have improved system bandwidth and reduced impedance.

Referring to FIG. 2 and FIG. 4, in some embodiments, the at least one backup semiconductor lasers is paired with the plurality of main semiconductor lasers in a one-to-one correspondence, and, a respective backup semiconductor laser, that is representative of each of the at least one backup semiconductor lasers, is coupled to a respective main optic fiber cable out of the plurality of main optic fiber cables, a respective main semiconductor laser paired with the respective backup semiconductor laser is also coupled to the respective main optic fiber cable. As such, because each main semiconductor laser is paired with a backup semiconductor laser and a pair of main semiconductor laser and backup semiconductor laser are coupled to the same optic fiber cable, this means that two semiconductor lasers are coupled to one optic fiber cable. Therefore, there is no need for digital routing operations to be performed on the transmitting end, i.e., the laser chip. The laser chip requires additional backup laser drivers as additional resources, provides the highest level of redundancy at 100%, does not require digital routing operations on either TX or RX, instead uses a laser switch between a pair of main semiconductor laser and backup semiconductor laser that are coupled to the same main optic fiber cable, and also have improved system bandwidth and reduced impedance.

Referring to FIGS. 2 and 5, in some embodiments, a total number of the at least one backup semiconductor lasers is a ratio of a total number of the plurality of main semiconductor lasers, and, the plurality of main semiconductor lasers are coupled to a plurality of main optic fiber cables respectively, the ratio is less than 100%. As such, the level of redundancy, i.e., the number of the backup semiconductor lasers relative to the number of main semiconductor lasers, is adjustable, and may be adjusted to cope with preferences.

Referring to FIG. 2 and FIG. 5, in some embodiments, the ratio is between 10% and 20%. As such, the laser chip is adaptive to various preferences.

Referring to FIG. 2 and FIG. 5, in some embodiments, the at least one backup semiconductor lasers is coupled to at least one backup optic fiber cables respectively, the laser chip is deployed on a transmitting end, and, digital routing operations are performed on the transmitting end and a receiving end associated with the transmitting end, such that data transmission via the selected one or more of the plurality of main semiconductor lasers and one or more of the plurality of main optic fiber cables associated with the selected one or more of the plurality of main semiconductor lasers is replaced by data transmission via the selected one or more of the at least one backup semiconductor lasers and one or more of the plurality of backup optic fiber cables associated with the selected one or more of the at least one backup semiconductor lasers. As such, the installment of additional optic fiber cables means that the backup semiconductor lasers may have their own backup optic fiber cables and saves the troubles of optical routing, and instead, digital routing which is simpler and faster than optical routing is needed. As such, digital routing operations are performed on the transmitting end, i.e., the laser chip, and on the receiving end, such as a GPU array that is optically connected with the laser chip, such that data transmission via the selected one or more of the plurality of main semiconductor lasers and one or more of the plurality of main optic fiber cables associated with the selected one or more of the plurality of main semiconductor lasers is replaced by data transmission via the selected one or more of the at least one backup semiconductor lasers and one or more of the plurality of backup optic fiber cables associated with the selected one or more of the at least one backup semiconductor lasers. And because such digital routing operations are performed in the digital domain, there is no involvement of optical routing and therefore does not involve complicated optical components.

Referring to FIG. 2 and FIG. 6, in some embodiments, the plurality of main semiconductor lasers is divided into a plurality of groups, and, the at least one backup semiconductor lasers are assigned to the plurality of groups, a respective backup semiconductor laser, that is representative of each of the at least one backup semiconductor lasers, is optically routed to be coupled to a respective main optic fiber cable out of the plurality of main optic fiber cables, a respective main semiconductor laser of a respective group out of the plurality of groups is coupled to the respective main optic fiber cable, the respective backup semiconductor laser is assigned to the respective group, the respective main semiconductor laser is from the selected one or more of the plurality of main semiconductor lasers. As such, by dividing the main semiconductor lasers into groups, it becomes economically practicable to add some optical components, such as the optical routers, on the TX side to allow the backup semiconductor laser's output, if selected, to be coupled to a selected main optic fiber cable, so that the malfunctioning main semiconductor laser corresponding to the selected main optic fiber cable may be shut down. The laser chip also does not require any additional backup optic fiber cables and may work with a level of redundancy lower than 100%, thereby making it adaptive to certain preferences.

Referring to FIG. 2 and FIG. 6, in some embodiments, the respective backup semiconductor laser is optically routed to be coupled to the respective main optic fiber by an optical router, and, the optical router includes an optical mirror and an optical switch. As such, since each backup semiconductor laser is responsible for only a fixed number of main semiconductor lasers within the same group, the backup semiconductor laser may be routed to be coupled to any of the several main optic fiber cables in the same group. This means that the optical routing operations are performed only on the RX side, and the TX side is not aware of the routing and merely receives optical signals from the several main optic fiber cables of the same group. The size of each group may be well calibrated to make sure that one backup semiconductor laser is not routed to too many main optic fiber cables, such as limited to 1 to 3, or 1 to 5.

Referring to FIG. 2 and FIG. 3 through FIG. 7, in some embodiments, the plurality of main laser drivers are interposed between the at least one selector and the plurality of main semiconductor lasers, and, the at least one backup laser drivers are interposed between the at least one selector and the at least one backup semiconductor lasers. As such, the placement of the selectors before the laser drivers means that additional backup laser drivers are needed, but this type of setting has benefits of reduced impedance because the laser driver is coupled to the semiconductor laser directly.

Referring to FIG. 2 and FIG. 7, in some embodiments, the laser chip further includes at least one secondary backup semiconductor lasers, that is configured for replacing malfunctioning backup semiconductor lasers out of the at least one backup semiconductor lasers. As such, the laser chip provides a secondary redundancy level at 10%, with respect to 200 backup semiconductor lasers, and therefore provides a secondary level of safeguards against laser burning out.

Referring to FIG. 2 and FIG. 8, in some embodiments, the at least one selector is interposed between the plurality of main laser drivers and the plurality of main semiconductor lasers, and, the at least one selector is interposed between the plurality of main laser drivers and the at least one backup semiconductor lasers, the at least one selector is further configured for selecting one or more of the plurality of main laser drivers associated with the selected one or more of the plurality of main semiconductor lasers, such that the selected one or more of the plurality of main laser drivers drives the selected one or more of the at least one backup semiconductor lasers for providing the one or more backup optical signals. As such, the placement of the selectors after the laser drivers means that there is no need for additional backup laser drivers, but this type of setting might have increased impedance, which may be diminished by adding a source follower to the source terminal of the laser driver. Also, by reusing the main optic fiber cables, it saves additional costs for the installment of additional optic fiber cables.

Referring to FIG. 2 and FIG. 8, in some embodiments, a total number of the at least one backup semiconductor lasers is 100% of a total number of the plurality of main semiconductor lasers, and, the plurality of main semiconductor lasers are coupled to a plurality of main optic fiber cables respectively. As such, it does not require any digital routing operations to be performed on the receiving end, such as a GPU array that is optically connected with the laser chip, because data transmission via the selected one or more of the plurality of main semiconductor lasers and one or more of the plurality of main optic fiber cables associated with the selected one or more of the plurality of main semiconductor lasers still goes through the same main optic fiber cable.

Referring to FIG. 2 and FIG. 7, in some embodiments, the at least one backup semiconductor lasers is paired with the plurality of main semiconductor lasers in a one-to-one correspondence, and, a respective backup semiconductor laser, that is representative of each of the at least one backup semiconductor lasers, is coupled to a respective main optic fiber cable out of the plurality of main optic fiber cables, a respective main semiconductor laser paired with the respective backup semiconductor laser is also coupled to the respective main optic fiber cable. As such, the laser chip does not require additional resources of laser drivers or backup optic fiber cables, provides the highest level of redundancy at 100%, does not require digital routing operations on either TX or RX, instead uses a laser switch between a pair of main semiconductor laser and backup semiconductor laser that are coupled to the same main optic fiber cable.

Referring to FIG. 2 and FIG. 9, in some embodiments, the at least one selector includes a plurality of 1-to-2 multiplexers, a respective 1-to-2 multiplexer out of the plurality of 1-to-2 multiplexers is connected to a respective main laser driver out of the plurality of main laser drivers that drives the respective main semiconductor laser, the respective 1-to-2 multiplexer is also connected to the respective main semiconductor laser and the respective backup semiconductor. As such, a mux is deployed for each pair of a main semiconductor laser and a backup semiconductor laser that shares the same main laser driver. The laser chip provides the highest redundancy level at 100%, and also keeps the number of main optic fiber cables unchanged, thereby preventing the involvement by the RX side.

Referring to FIG. 2, in some embodiments, the plurality of main semiconductor lasers are Vertical-Cavity Surface-Emitting Lasers (VCSELs), Edge-Emitting Lasers (EELs), or, Light-Emitting Diodes (LEDs), and, the laser chip is incorporated into an optical transceiver. As such, the laser chip is adaptive to various preferences.

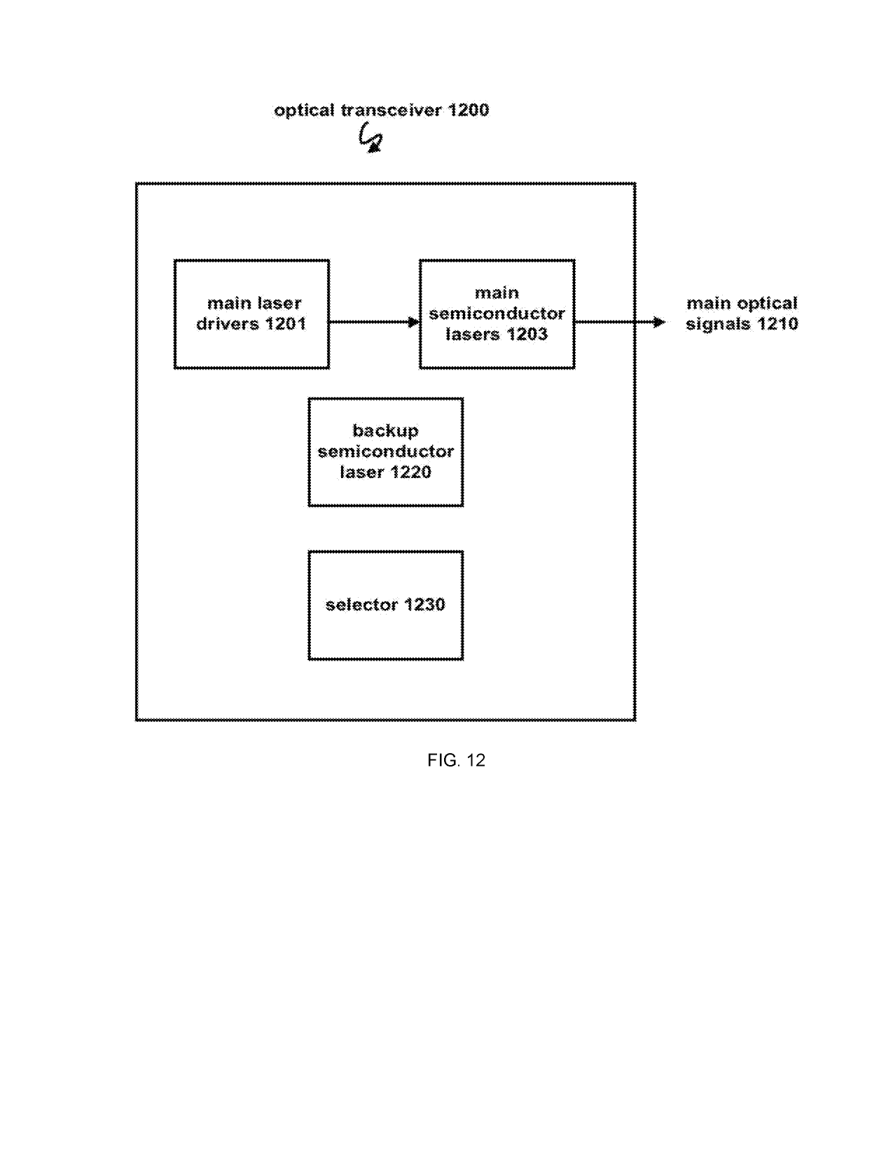

Referring to FIG. 12, FIG. 12 is a schematic diagram illustrating an optical transceiver according to some embodiments. The optical transceiver 1200 includes: a plurality of main laser drivers 1201, configured for providing a plurality of pulsed currents; a plurality of main semiconductor lasers 1203, configured for providing a plurality of main optical signals 1210 in response to the plurality of pulsed currents respectively; and at least one backup semiconductor lasers 1220. The selector 1230 is configured for selecting one or more of the plurality of main semiconductor lasers 1201, and, selecting one or more of the at least one backup semiconductor lasers to replace the selected one or more of the plurality of main semiconductor lasers, such that the selected one or more of the at least one backup semiconductor lasers provides one or more backup optical signals that serves to replace one or more of the plurality of main optical signals 1210 associated with the selected one or more of the plurality of main semiconductor lasers.

As such, the architecture and selection mechanism of the optical transceiver 1200 provides an optoelectronic solution for optical connectors used in AI-driven data centers, with good reliability and cost efficiency. The architecture of the optical transceiver 1200 provides several aspects for parametrization of the optical transceiver for optimization, including the level of redundancy, i.e., the number of the backup semiconductor lasers relative to the number of main semiconductor lasers, the implementation details of the at least one selector, the placement of the selectors before or after the laser drivers, the installment of additional optic fiber cables. As such, the architecture of the optical transceiver 1200 provides several aspects for parametrization, for configuring the optical transceiver to reach a well balance among different factors like system stability, cost efficiency, system bandwidth, cost sensitivity, and circuit area. Therefore, the architecture of the optical transceiver 1200 supports an optoelectronic solution for optical connectors used in AI-driven data centers, with good reliability and cost efficiency, that is adaptive to customer preferences with a variety of configurable parameters.

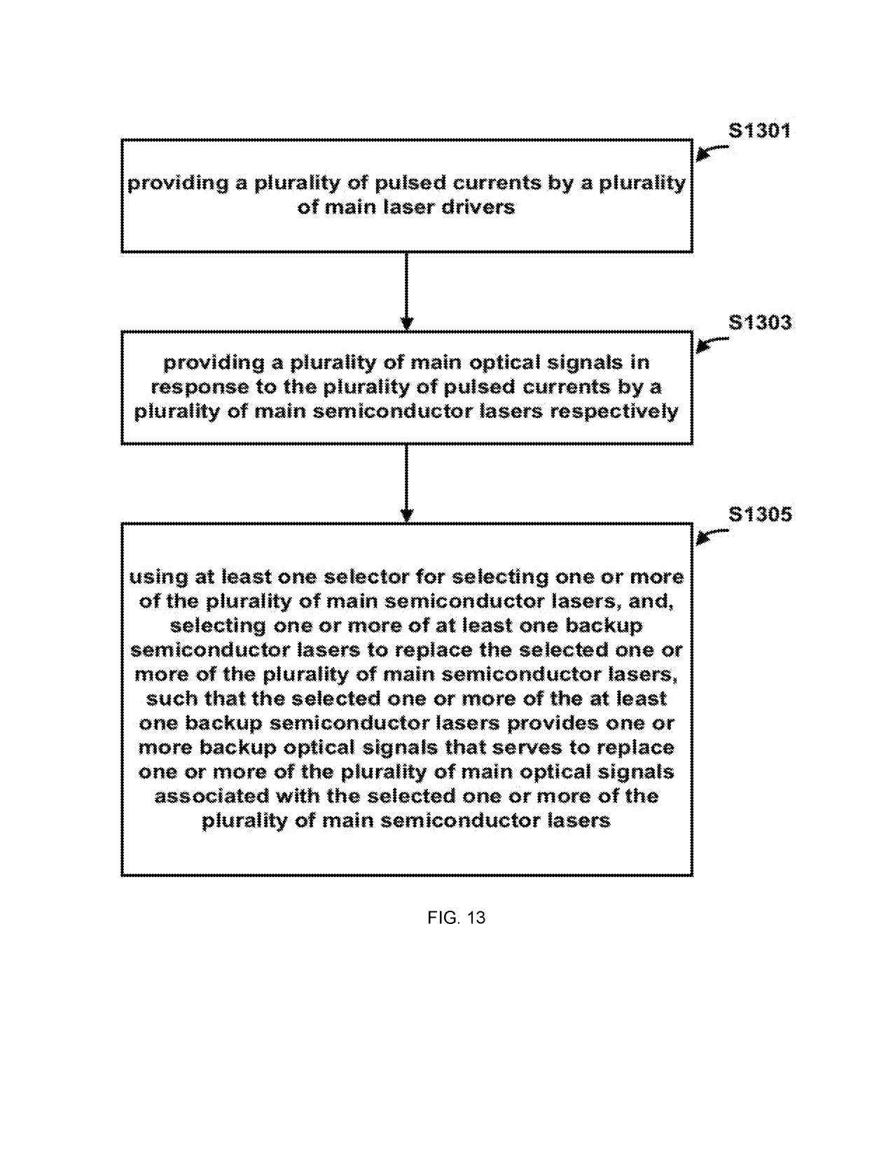

Referring to FIG. 13, FIG. 13 is a flow chart illustrating a method for managing multiple laser channels according to some embodiments. As shown in FIG. 13, the method includes the following steps.

Step S1301: providing a plurality of pulsed currents by a plurality of main laser drivers.

Step S1303: providing a plurality of main optical signals in response to the plurality of pulsed currents by a plurality of main semiconductor lasers respectively.

Step S1305: using at least one selector for selecting one or more of the plurality of main semiconductor lasers, and, selecting one or more of at least one backup semiconductor lasers to replace the selected one or more of the plurality of main semiconductor lasers, such that the selected one or more of the at least one backup semiconductor lasers provides one or more backup optical signals that serves to replace one or more of the plurality of main optical signals associated with the selected one or more of the plurality of main semiconductor lasers.

As such, the method supports an optoelectronic solution for optical connectors used in AI-driven data centers, with good reliability and cost efficiency, that is adaptive to customer preferences with a variety of configurable parameters.

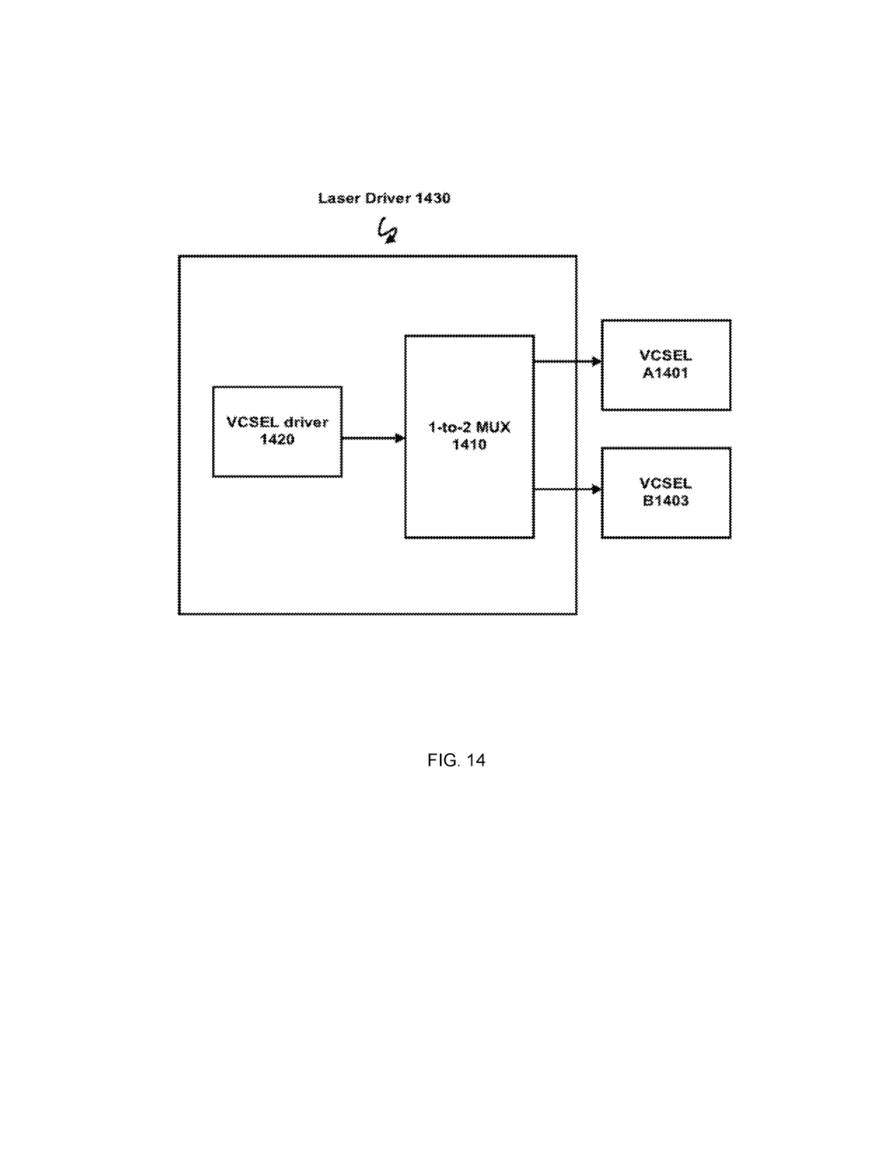

Referring to FIG. 14, FIG. 14 is a schematic diagram illustrating a VCSEL chip suitable for high-speed data transmission according to some embodiments. The VCSEL chip includes a laser driver 1430 for providing the pulsed current for driving a VCSEL. The VCSEL chip includes two VCSELs, VCSEL A1401 and VCSEL B1403. The laser driver 1430 includes a VCSEL driver 1420 and a 1-to-2 MUX 1410. FIG. 14 illustrates a usage scenario where one VCSEL is in use while another VCSEL is in spare. The 1-to-2 MUX 1410 receives the outputs from the VCSEL driver 1420 as the one input, and is connected with the two VCSELs as the two outputs. The 1-to-2 MUX 1410 serves to select between the two VCSELs, so that one VCSEL is driven by the pulsed current provided by the laser driver 1430 and therefore is in use, while, the other VCSEL is in spare. The selection between the two VCSELs may be based on performance evaluation. For example, if VCSEL A1401 is identified as unreliable, then the 1-to-2 MUX 1410 switches to VCSEL B1403. As such, by providing a redundant VCSEL that is in spare, the VCSEL chip is suitable for high-speed data transmission, and provides an optoelectronic solution for optical connectors used in AI-driven data centers, with good reliability and cost efficiency. For instance, the VCSEL chip may be used for 224 GB PAM4 data transmission.

To the extent that the term "includes" or "including" is employed in the detailed description or the claims, it is intended to be inclusive in a manner similar to the term "comprising" as that term is interpreted when employed as a transitional word in a claim. Furthermore, to the extent that the term "or" is employed in the detailed description or claims (e.g., A or B) it is intended to mean "A or B or both." When the applicants intend to indicate "only A or B but not both" then the term "only A or B but not both" will be employed. Thus, use of the term "or" herein is the inclusive, and not the exclusive use. See, Bryan A. Garner, A Dictionary of Modern Legal Usage 624 (2d. Ed. 1995).

While example systems, methods, and so on, have been illustrated by describing examples, and while the examples have been described in considerable detail, it is not the intention of the applicants to restrict or in any way limit scope to such detail. It is, of course, not possible to describe every conceivable combination of components or methodologies for purposes of describing the systems, methods, and so on, described herein. Additional advantages and modifications will readily appear to those skilled in the art. Therefore, the invention is not limited to the specific details, the representative apparatus, and illustrative examples shown and described. Thus, this application is intended to embrace alterations, modifications, and variations that fall within the scope of the appended claims. Furthermore, the preceding description is not meant to limit the scope of the invention. Rather, the scope of the invention is to be determined by the appended claims and their equivalents.

The detailed embodiments provided in the present disclosure can be implemented by any one or a combination of hardware, software, firmware, or solid-state logic circuits, and can be implemented in combination with signal processing, control, and/or dedicated circuits. The equipment(s) or device(s) provided in the detailed embodiments of the present disclosure may include one or more processors (a microprocessor, a controller, a digital signal processor (DSP), an application specific integrated circuit (ASIC), a field programmable gate array(FPGA) and so on), and these processors process various computer-executable instructions to control the operations of the equipment(s) or device(s). The equipment(s) or device(s) provided in the detailed embodiments of the present disclosure may include a system bus or a data transmission system that couples various components together. The system bus may include any one of different bus structures or a combination of different bus structures, such as a memory bus or a memory controller, a peripheral bus, a universal serial bus, and/or a process or a local bus using any of a variety of bus architectures. The equipment(s) or device(s) provided in the detailed embodiments of the present disclosure may be provided separately, may also be a part of the system, or may be a part of other equipment or devices.

The detailed embodiments provided by the present disclosure may include a computer-readable storage medium or a combination with a computer-readable storage medium, such as one or more storage devices capable of providing non-transitory data storage. The computer-readable storage medium/storage device may be configured to store data, programmers and/or instructions, which when executed by the processor of the equipment(s) or device(s) provided in the present disclosure, would allow the equipment(s) or device(s) to implement related operations. The computer-readable storage medium/storage device may include one or more of the following characteristics: volatile, nonvolatile, dynamic, static, read/write, read-only, random access, sequential access, location addressability, file addressability and content addressability. In one or more exemplary embodiments, the computer-readable storage medium/storage device may be integrated into the equipment(s) or device(s) provided in the detailed embodiments of the present disclosure or belong to a public system. The computer-readable storage media/storage devices can include optical storage devices, semiconductor storage devices and/or magnetic storage devices, etc., and can also include random access memory (RAM), flash memory, read-only memory (ROM), erasable and programmable read-only memory (EPROM), electrically erasable programmable read-only memory (EEPROM), registers, hard disk, removable disk, recordable and/or rewritable compact disc (CD), digital versatile disc (DVD), large capacity storage medium device or any other form of suitable storage medium.

It will be appreciated that various of the above-disclosed embodiments and other features and functions, or alternatives or varieties thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A laser chip, comprising:
a plurality of main laser drivers, configured for providing a plurality of pulsed currents;
a plurality of main semiconductor lasers, configured for providing a plurality of main optical signals in response to the plurality of pulsed currents respectively;
at least one backup semiconductor lasers; and
at least one selector, configured for selecting one or more of the plurality of main semiconductor lasers, and, selecting one or more of the at least one backup semiconductor lasers to replace the selected one or more of the plurality of main semiconductor lasers, such that the selected one or more of the at least one backup semiconductor lasers provides one or more backup optical signals that serves to replace one or more of the plurality of main optical signals associated with the selected one or more of the plurality of main semiconductor lasers.

2. The laser chip according to claim 1, wherein the selected one or more of the at least one backup semiconductor lasers replaces the selected one or more of the plurality of main semiconductor lasers in a one-to-one correspondence.

3. The laser chip according to claim 2, the laser chip further comprises at least one backup laser drivers that is configured for driving the at least one backup semiconductor lasers respectively, and, the at least one selector is further configured for selecting one or more of the at least one backup laser drivers associated with the selected one or more of the at least one backup semiconductor lasers, such that the selected one or more of the at least one backup laser drivers drives the selected one or more of the at least one backup semiconductor lasers for providing the one or more backup optical signals.

4. The laser chip according to claim 3, wherein a total number of the at least one backup semiconductor lasers is 100% of a total number of the plurality of main semiconductor lasers, and, the plurality of main semiconductor lasers are coupled to a plurality of main optic fiber cables respectively.

5. The laser chip according to claim 4, wherein, the at least one backup semiconductor lasers is coupled to at least one backup optic fiber cables respectively, the laser chip is deployed on a transmitting end, and, digital routing operations are performed on the transmitting end and a receiving end associated with the transmitting end, such that data transmission via the selected one or more of the plurality of main semiconductor lasers and one or more of the plurality of main optic fiber cables associated with the selected one or more of the plurality of main semiconductor lasers is replaced by data transmission via the selected one or more of the at least one backup semiconductor lasers and one or more of the plurality of backup optic fiber cables associated with the selected one or more of the at least one backup semiconductor lasers.

6. The laser chip according to claim 4, wherein, the at least one backup semiconductor lasers is paired with the plurality of main semiconductor lasers in a one-to-one correspondence, and, a respective backup semiconductor laser, that is representative of each of the at least one backup semiconductor lasers, is coupled to a respective main optic fiber cable out of the plurality of main optic fiber cables, wherein a respective main semiconductor laser paired with the respective backup semiconductor laser is also coupled to the respective main optic fiber cable.

7. The laser chip according to claim 3, wherein a total number of the at least one backup semiconductor lasers is a ratio of a total number of the plurality of main semiconductor lasers, and, the plurality of main semiconductor lasers are coupled to a plurality of main optic fiber cables respectively, wherein the ratio is less than 100%.

8. The laser chip according to claim 7, wherein the ratio is between 10% and 20%.

9. The laser chip according to claim 7, wherein, the at least one backup semiconductor lasers is coupled to at least one backup optic fiber cables respectively, the laser chip is deployed on a transmitting end, and, digital routing operations are performed on the transmitting end and a receiving end associated with the transmitting end, such that data transmission via the selected one or more of the plurality of main semiconductor lasers and one or more of the plurality of main optic fiber cables associated with the selected one or more of the plurality of main semiconductor lasers is replaced by data transmission via the selected one or more of the at least one backup semiconductor lasers and one or more of the plurality of backup optic fiber cables associated with the selected one or more of the at least one backup semiconductor lasers.

10. The laser chip according to claim 7, wherein, the plurality of main semiconductor lasers is divided into a plurality of groups, and, the at least one backup semiconductor lasers are assigned to the plurality of groups, wherein, a respective backup semiconductor laser, that is representative of each of the at least one backup semiconductor lasers, is optically routed to be coupled to a respective main optic fiber cable out of the plurality of main optic fiber cables, a respective main semiconductor laser of a respective group out of the plurality of groups is coupled to the respective main optic fiber cable, the respective backup semiconductor laser is assigned to the respective group, the respective main semiconductor laser is from the selected one or more of the plurality of main semiconductor lasers.

11. The laser chip according to claim 10, wherein the respective backup semiconductor laser is optically routed to be coupled to the respective main optic fiber by an optical router, and, the optical router includes an optical mirror and an optical switch.

12. The laser chip according to claim 3, wherein the plurality of main laser drivers are interposed between the at least one selector and the plurality of main semiconductor lasers, and, the at least one backup laser drivers are interposed between the at least one selector and the at least one backup semiconductor lasers.

13. The laser chip according to claim 3, wherein the laser chip further comprises at least one secondary backup semiconductor lasers, that is configured for replacing malfunctioning backup semiconductor lasers out of the at least one backup semiconductor lasers.

14. The laser chip according to claim 2, wherein the at least one selector is interposed between the plurality of main laser drivers and the plurality of main semiconductor lasers, and, the at least one selector is interposed between the plurality of main laser drivers and the at least one backup semiconductor lasers, wherein the at least one selector is further configured for selecting one or more of the plurality of main laser drivers associated with the selected one or more of the plurality of main semiconductor lasers, such that the selected one or more of the plurality of main laser drivers drives the selected one or more of the at least one backup semiconductor lasers for providing the one or more backup optical signals.

15. The laser chip according to claim 14, wherein a total number of the at least one backup semiconductor lasers is 100% of a total number of the plurality of main semiconductor lasers, and, the plurality of main semiconductor lasers are coupled to a plurality of main optic fiber cables respectively.

16. The laser chip according to claim 15, wherein, the at least one backup semiconductor lasers is paired with the plurality of main semiconductor lasers in a one-to-one correspondence, and, a respective backup semiconductor laser, that is representative of each of the at least one backup semiconductor lasers, is coupled to a respective main optic fiber cable out of the plurality of main optic fiber cables, wherein a respective main semiconductor laser paired with the respective backup semiconductor laser is also coupled to the respective main optic fiber cable.

17. The laser chip according to claim 16, wherein, the at least one selector includes a plurality of 1-to-2 multiplexers, a respective 1-to-2 multiplexer out of the plurality of 1-to-2 multiplexers is connected to a respective main laser driver out of the plurality of main laser drivers that drives the respective main semiconductor laser, the respective 1-to-2 multiplexer is also connected to the respective main semiconductor laser and the respective backup semiconductor.

18. The laser chip according to claim 1, wherein the plurality of main semiconductor lasers are Vertical-Cavity Surface-Emitting Lasers (VCSELs), Edge-Emitting Lasers (EELs), or, Light-Emitting Diodes (LEDs), and, the laser chip is incorporated into an optical transceiver.

19. A selector of an optical transceiver, wherein the optical transceiver comprises:
a plurality of main laser drivers, configured for providing a plurality of pulsed currents;
a plurality of main semiconductor lasers, configured for providing a plurality of main optical signals in response to the plurality of pulsed currents respectively; and
at least one backup semiconductor lasers,
wherein the selector is configured for selecting one or more of the plurality of main semiconductor lasers, and, selecting one or more of the at least one backup semiconductor lasers to replace the selected one or more of the plurality of main semiconductor lasers, such that the selected one or more of the at least one backup semiconductor lasers provides one or more backup optical signals that serves to replace one or more of the plurality of main optical signals associated with the selected one or more of the plurality of main semiconductor lasers.

20. A method for managing multiple laser channels, comprising:
providing a plurality of pulsed currents by a plurality of main laser drivers;
providing a plurality of main optical signals in response to the plurality of pulsed currents by a plurality of main semiconductor lasers respectively; and
using at least one selector for selecting one or more of the plurality of main semiconductor lasers, and, selecting one or more of at least one backup semiconductor lasers to replace the selected one or more of the plurality of main semiconductor lasers, such that the selected one or more of the at least one backup semiconductor lasers provides one or more backup optical signals that serves to replace one or more of the plurality of main optical signals associated with the selected one or more of the plurality of main semiconductor lasers.
